(19) United States
(12) Patent Application Publication
(10) Pub. No.: US 2011/0059403 A1
(43) Pub. Date: Mar. 10, 2011

(54) METHOD OF FORMING WIRING PATTERN, METHOD OF FORMING SEMICONDUCTOR DEVICE, SEMICONDUCTOR DEVICE, AND DATA PROCESSING SYSTEM

(75) Inventor: Mitsunari SUKEKAWA, Tokyo (JP)

(73) Assignee: ELPIDA MEMORY, INC., Tokyo (JP)

(21) Appl. No.: 12/877,212

(22) Filed: Sep. 8, 2010

(30) Foreign Application Priority Data
Sep. 10, 2009 (JP) 2009-209116

(51) Int. Cl. G03F 7/20

(52) U.S. Cl. 430/312; 430/322; 430/323

(57) ABSTRACT

A method of forming a pattern includes the following processes. A first lithography process is performed. The first lithography process is applied to a first region of a substrate. A second lithography process is performed. The second lithography process is applied to the first region and to a second region of the substrate, to form a first pattern in the first region, and to form a second pattern in the second region. The first pattern is defined by a first dimension. The first dimension is smaller than a resolution limit of lithography. The second pattern is defined by a second dimension. The second dimension is equal to or greater than the resolution limit of lithography.

### BACKGROUND OF THE INVENTION

1. Field of the Invention

The present invention relates to a method of forming wiring pattern, a method of forming semiconductor device, a semiconductor device, and a data processing system. The present invention relates in particular to a wiring pattern forming method and a semiconductor device manufacturing method that is suitable when forming a fine wiring pattern with dimensions that are smaller than the resolution limit in lithography technology.

Priority is claimed on Japanese Patent Application No. 2009-209116, filed Sep. 10, 2009, the content of which is incorporated herein by reference.

2. Description of the Related Art

Japanese Unexamined Patent Application, First Publications, Nos. JP-A-2008-91925 and JP-A-2008-91927 disclose that as a technique of forming wiring patterns, such as a word line and a bit line which form a memory cell of a semiconductor device provided in a data processing system or the like, there is a technique of forming a fine pattern with dimensions that are smaller than the resolution limit of lithography technology.

Examples of such a technique include self-aligned double patterning, hereinafter referred to an SADP method. Sidewalls are formed on side walls of a core pattern by lithography and dry etching. The same material as the core pattern is embedded between the sidewalls. Then double pitch processing on a lithography pattern is performed using the core pattern or the sidewalls as a mask.

Japanese Unexamined Patent Application, First Publication, No. JP-A-2008-27978 discloses a method of forming fine wiring patterns with dimensions, which are equal to or less than the resolution limit of lithography, in a memory cell array using the above technique and also forming normal wiring patterns, which depend on the resolution of lithography, simultaneously in a peripheral circuit or the like.

Generally, when forming a repeated pattern of lines and spaces which becomes a wiring pattern of a semiconductor device, it is necessary to form a lead-out pad pattern for electrical contact at the end of each wiring line. In the known SADP method, a lead-out pad pattern with a different width from a wiring line cannot be formed simultaneously with the wiring line. For this reason, the lead-out pad pattern should be separately formed using another exposure process which is not the exposure process for forming the wiring pattern using the SADP method.

Japanese Unexamined Patent Application, First Publication, No. JP-A-2003-224172 discloses examples of a technique of forming a wiring pattern of a semiconductor device include a technique of forming a pad pattern, the width of which is larger than the line width of a wiring pattern, at the end of the wiring pattern.

Japanese Unexamined Patent Application, First Publication, No. JP-A-2008-27978 discloses the SADP method, in which it is necessary to implant ions only to the hard mask on a peripheral circuit in order to separate a fine wiring pattern in a memory cell from a normal pattern of the peripheral circuit. Accordingly, since a lithography process is further required, there is a problem in that the process becomes complicated.

In addition, if sidewalls are formed on the core pattern in a memory cell, the sidewalls are formed to surround the entire periphery of the core pattern. Accordingly, it is necessary to remove the sidewall formed at the end of the wiring pattern in the longitudinal direction thereof. However, the removal process is not disclosed in Japanese Unexamined Patent Application, First Publication, No. JP-A-2008-27978.

Moreover, the formation of a lead-out pad, which is essential for a wiring pattern, is not disclosed. Accordingly, since it is necessary to further perform a process for forming the lead-out pad after forming a fine wiring pattern using the SADP method, there is a problem in that the manufacturing process becomes very complicated.

In addition, a lead-out pad pattern with a different width from a wiring pattern could be formed neither by the SADP method nor by other known techniques. For this reason, it was necessary to form a fine wiring line with a dimension less than the resolution limit using the SADP method and then to form a lead-out pad pattern at the end of the wiring line using a plurality of separate exposure processes. In this case, however, since the matching accuracy of the lead-out pad pattern with respect to the wiring line in lithography is not sufficient, the lead-out pad and the adjacent wiring line may be short-circuited.

Moreover, in the known technique, not only is the exposure process for forming a wiring pattern needed, but also the lead-out pattern for electrical contact is formed using a plurality of exposure processes. Accordingly, there is a demand to reduce the number of manufacturing processes including the exposure processes.

### SUMMARY

In one embodiment, a method of forming a pattern may include, but is not limited to, the following processes. A first lithography process is performed. The first lithography process is applied to a first region of a substrate. A second lithography process is performed. The second lithography process is applied to the first region and to a second region of the substrate, to form a first pattern in the first region, and to form a second pattern in the second region. The first pattern is defined by a first dimension. The first dimension is smaller than a resolution limit of lithography. The second pattern is defined by a second dimension. The second dimension is equal to or greater than the resolution limit of lithography.

In another embodiment, a method of forming a wiring pattern may include, but is not limited to, the following processes. A first lithography process is performed. The first lithography process is applied to a first region of a substrate. A second lithography process is performed. The second lithography process is applied to the first region and to a second region of the substrate, to form a first pattern in the first region, and to form a second pattern in the second region. The first pattern may include, but is not limited to, first and second lines that are separated by a first space. The first and second lines have a first line width. The first space has a first space width. The first line width and the first space width are smaller than a resolution limit of lithography. The second pattern may include, but is not limited to, third and fourth lines that are separated by a second space. The third and fourth lines have a second line width. The second space has a second space width. The second line width and the second space width are equal to or greater than the resolution limit of lithography.

In still another embodiment, a method of forming a wiring pattern may include, but is not limited to, the following processes. A first layer is formed over a substrate having first and second regions. A first resist pattern is formed over the first layer. A first etching process is performed using the first resist pattern as a first mask to selectively etch the first layer in the first region and form a first-original pattern in the first region. The first resist pattern is removed. The first-original pattern is processed to form a second-original pattern. The second-original pattern is defined by a first dimension that is smaller than a resolution limit of lithography. A second resist pattern is formed over the first layer having the second-original pattern. A second etching process is performed using the second resist pattern as a second mask to selectively etch the first layer in the first region and the second region, to form a first pattern in the first region, and to form a second pattern in the second region. The first pattern is defined by the first dimension. The second pattern is defined by a second dimension that is equal to or greater than the resolution limit of lithography.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a fragmentally plan view illustrating a semiconductor substrate in a step involved in a method of forming wiring patterns in accordance with a first preferred embodiment of the present invention;

FIG. 1B is a fragmentally cross sectional elevation view, taken along an A-A′ line of FIG. 1A;

FIG. 1C is a fragmentally enlarged plan view of FIG. 1A;

FIG. 2A is a fragmentally plan view illustrating the semiconductor substrate in a step subsequent to the step of FIG. 1A, involved in the method of forming wiring patterns in accordance with the first preferred embodiment of the present invention;

FIG. 2B is a fragmentally cross sectional elevation view, taken along an A-A′ line of FIG. 2A;

FIG. 3A is a fragmentally plan view illustrating the semiconductor substrate in a step subsequent to the step of FIG. 2A, involved in the method of forming wiring patterns in accordance with the first preferred embodiment of the present invention;

FIG. 3B is a fragmentally cross sectional elevation view, taken along an A-A′ line of FIG. 3A;

FIG. 4A is a fragmentally plan view illustrating the semiconductor substrate in a step subsequent to the step of FIG. 3A, involved in the method of forming wiring patterns in accordance with the first preferred embodiment of the present invention;

FIG. 4B is a fragmentally cross sectional elevation view, taken along an A-A′ line of FIG. 4A;

FIG. 5A is a fragmentally plan view illustrating the semiconductor substrate in a step subsequent to the step of FIG. 4A, involved in the method of forming wiring patterns in accordance with the first preferred embodiment of the present invention;

FIG. 5B is a fragmentally cross sectional elevation view, taken along an A-A′ line of FIG. 5A;

FIG. 6A is a fragmentally plan view illustrating the semiconductor substrate in a step subsequent to the step of FIG. 5A, involved in the method of forming wiring patterns in accordance with the first preferred embodiment of the present invention;

FIG. 6B is a fragmentally cross sectional elevation view, taken along an A-A′ line of FIG. 6A;

FIG. 7A is a fragmentally plan view illustrating the semiconductor substrate in a step subsequent to the step of FIG. 6A, involved in the method of forming wiring patterns in accordance with the first preferred embodiment of the present invention;

FIG. 7B is a fragmentally cross sectional elevation view, taken along an A-A′ line of FIG. 7A;

FIG. 8A is a fragmentally plan view illustrating the semiconductor substrate in a step subsequent to the step of FIG. 7A, involved in the method of forming wiring patterns in accordance with the first preferred embodiment of the present invention;

FIG. 8B is a fragmentally cross sectional elevation view, taken along an A-A′ line of FIG. 8A;

FIG. 9A is a fragmentally plan view illustrating the semiconductor substrate in a step subsequent to the step of FIG. 8A, involved in the method of forming wiring patterns in accordance with the first preferred embodiment of the present invention;

FIG. 9B is a fragmentally cross sectional elevation view, taken along an A-A′ line of FIG. 9A;

FIG. 10A is a fragmentally plan view illustrating the semiconductor substrate with wiring patterns formed by the method shown in FIGS. 1A through 9B in accordance with the first preferred embodiment of the present invention;

FIG. 10B is a fragmentally cross sectional elevation view, taken along an A-A′ line of FIG. 10A;

FIG. 11 is a fragmentally plan view illustrating wiring patterns in accordance with a second preferred embodiment of the present invention; and

FIG. 12 is a block diagram illustrating a data processing system including a DRAM including wiring patterns formed by the method shown in FIGS. 1A through 9B.

### DETAILED DESCRIPTION OF THE PREFERRED EMBODIMENTS

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a method of forming a pattern may include, but is not limited to, the following processes. A first lithography process is performed. The first lithography process is applied to a first region of a substrate. A second lithography process is performed. The second lithography process is applied to the first region and to a second region of the substrate, to form a first pattern in the first region, and to form a second pattern in the second region. The first pattern is defined by a first dimension. The first dimension is smaller than a resolution limit of lithography. The second pattern is defined by a second dimension. The second dimension is equal to or greater than the resolution limit of lithography.

In some cases, the first pattern may include, but is not limited to, a first wiring pattern. The first wiring pattern may include, but is not limited to, a line portion and an expended portion. The line portion has a first width smaller than the resolution limit of lithography. The expended portion is greater in width than the line portion.

In some cases, the first lithography process may include, but is not limited to the following processes. A first resist pattern is formed over a first layer. The first layer extends over the first region and the second region of the substrate. A first etching process is performed using the first resist pattern as a first mask to selectively etch the first layer in the first region to form a first-original pattern in the first region. The first resist pattern is removed. The first-original pattern is processed to form a second-original pattern. The second-original pattern is defined by the first dimension that is smaller than the resolution limit of lithography. The second lithography process may include, but is not limited to, the following processes. A second resist pattern is formed over the first layer. A second etching process is performed using the second resist pattern as a second mask to selectively etch the first layer in the first region and the second region.

In some cases, the second etching process may selectively etch the first layer to form the first pattern in the first region and the second pattern in the second region simultaneously.

In some cases, the first-original pattern may include, but is not limited to, a plurality of first L-shaped lines. Each of the plurality of first L-shaped lines may include, but is not limited to, a line portion and an expanded portion. The first L-shaped lines are aligned at a constant pitch in a first direction. The first direction is perpendicular to a second direction along which the line portions extend. The expanded portions expand in the first direction. The expanded portion of each of the first L-shaped lines is positioned outside, in the second direction, the line portion of an adjacent one of the first L-shaped lines. The expanded portions of two adjacent ones of the first L-shaped lines are positioned at opposite sides in the second direction. In some cases, the method may further include, but is not limited to, the following processes. A second layer is formed over the substrate. The first layer is formed over the second layer, before performing the first lithography process. The first-original pattern is formed in the first layer.

In some cases, the second etching process may be performed using the second resist pattern as the second mask by selectively etching the first layer to form the second pattern in the first layer.

In some cases, the first-original pattern may be processed to form the second-original pattern by the following processes. A side wall layer is formed, without filling up first grooves of the first-original pattern. The side wall layer extends on side wall surfaces of the first-original pattern and on an upper surface of the first layer, the side wall layer being different in material than the first layer.

The side wall layer is etched back to form side walls on the side wall surfaces of the first-original pattern. The side walls define second grooves that are narrower than the first grooves. A third layer is formed which fills up the second grooves of the first-original pattern. The third layer is the same in material as the first layer. The third layer and the first layer are etched back so that upper portions of the side walls project from an etched surface of the first layer. The side walls are removed to form the second-original pattern.

In some cases, the first pattern may be formed by performing the second lithography process to the first region having the second-original pattern.

In some cases, the second-original pattern may include, but is not limited to, a plurality of second L-shaped lines. Each of the plurality of second L-shaped lines may include, but is not limited to, a line portion and an expanded portion. The line portion has a first width as the first dimension. The first width is smaller than the resolution limit of lithography. The plurality of second L-shaped lines are aligned in a first direction perpendicular to a second direction along which the plurality of second L-shaped lines are aligned in parallel to each other. The second resist pattern has an opening that includes first, second, third and fourth edges of the second L-shaped lines. The first and second edges are parallel to each other and extend along the first direction. The third and fourth lines are parallel to each other and extend along the second direction. The first edge is a first edge of the line portion of a first one of the second L-shaped lines. The second edge is a first edge of the expanded portion of a second one of the second L-shaped lines. The second one is adjacent to the first one. The third edge is a second edge of the line portion of the first one of the second L-shaped lines. The fourth edge is a second edge of the expanded portion of the second one of the second L-shaped lines.

In some cases, the second resist pattern may have first, second, third and fourth peripheral edges. The first, second and third peripheral edges are positioned inside the peripheral edges of the first region by a width of the second grooves. The fourth peripheral edge is aligned to the peripheral edge of the first region.

In some cases, the first region may be a memory cell region, and the second region may be a peripheral circuit region.

In some cases, the first pattern may include, but is not limited to, at least one of a word line pattern and a bit line pattern.

In some cases, the first lithography process may be performed by using a first resist pattern. The first resist pattern may include, but is not limited to, a plurality of third L-shaped lines. Each of the plurality of third L-shaped lines may include, but is not limited to, a line portion and an expanded portion. The line portion has a first width as the first dimension. The first width is smaller than the resolution limit of lithography. The expanded portion has a second width that is three times wider than the first width. The third L-shaped lines are aligned at a constant pitch in a first direction. The first direction is perpendicular to a second direction along which the line portions extend. The first constant pitch is two times greater than the first width. The expanded portions expand in the first direction.

In another embodiment, a method of forming a wiring pattern may include, but is not limited to, the following processes. A first lithography process is performed. The first lithography process is applied to a first region of a substrate. A second lithography process is performed. The second lithography process is applied to the first region and to a second region of the substrate, to form a first pattern in the first region, and to form a second pattern in the second region. The first pattern may include, but is not limited to, first and second lines that are separated by a first space. The first and second lines have a first line width. The first space has a first space width. The first line width and the first space width are smaller than a resolution limit of lithography. The second pattern may include, but is not limited to, third and fourth lines that are separated by a second space. The third and fourth lines have a second line width. The second space has a second space width. The second line width and the second space width are equal to or greater than the resolution limit of lithography.

In some cases, the first lithography process may include, but is not limited to, the following processes. A first resist pattern is formed over a first layer over the substrate. The first layer extends over the first region and the second region of the substrate. A first etching process is performed using the first resist pattern as a first mask to selectively etch the first layer in the first region and form a first-original pattern in the first region. The first resist pattern is removed. The first-original pattern is processed to form a second-original pattern. The second-original pattern is defined by the first dimension that is smaller than the resolution limit of lithography. The second lithography process may include, but is not limited to, the following processes. A second resist pattern is formed over the first layer. A second etching process is performed using the second resist pattern as a second mask to selectively etch the first layer in the first region and the second region.

In some cases, the first lithography process may be performed by using a first resist pattern. The first resist pattern may include, but is not limited to, a plurality of third L-shaped lines. Each of the plurality of third L-shaped lines may include, but is not limited to, a line portion and an expanded portion. The line portion has a first width as the first dimension. The first width is smaller than the resolution limit of lithography. The expanded portion has a second width being three times wider than the first width. The third L-shaped lines are aligned at a constant pitch in a first direction. The first direction is perpendicular to a second direction along which the line portions extend. The first constant pitch is two times greater than the first width. The expanded portions expand in the first direction.

In still another embodiment, a method of forming a wiring pattern may include, but is not limited to, the following processes. A first layer is formed over a substrate having first and second regions. A first resist pattern is formed over the first layer. A first etching process is performed using the first resist pattern as a first mask to selectively etch the first layer in the first region and form a first-original pattern in the first region. The first resist pattern is removed. The first-original pattern is processed to form a second-original pattern. The second-original pattern is defined by a first dimension that is smaller than a resolution limit of lithography. A second resist pattern is formed over the first layer having the second-original pattern. A second etching process is performed using the second resist pattern as a second mask to selectively etch the first layer in the first region and the second region, to form a first pattern in the first region, and to form a second pattern in the second region. The first pattern is defined by the first dimension. The second pattern is defined by a second dimension that is equal to or greater than the resolution limit of lithography.

In some cases, the first-original pattern is processed to form the second-original pattern by the following processes. A side wall layer is formed, without filling up first grooves of the first-original pattern. The side wall layer extends on side wall surfaces of the first-original pattern and on an upper surface of the first layer. The side wall layer is different in material than the first layer. The side wall layer is etched back to form side walls on the side wall surfaces of the first-original pattern. The side walls define second grooves that are narrower than the first grooves. A third layer is formed which fills up the second grooves of the first-original pattern. The third layer is the same in material as the first layer. The third layer and the first layer are etched back so that upper portions of the side walls project from an etched surface of the first layer. The side walls are removed to form the second-original pattern.

In some cases, the first lithography process may be performed by using a first resist pattern. The first resist pattern may include, but is not limited to, a plurality of third L-shaped lines. Each of the plurality of third L-shaped lines may include, but is not limited to, a line portion and an expanded portion. The line portion has a first width as the first dimension. The first width is smaller than the resolution limit of lithography. The expanded portion has a second width being three times wider than the first width. The third L-shaped lines are aligned at a constant pitch in a first direction. The first direction is perpendicular to a second direction along which the line portions extend. The first constant pitch is two times greater than the first width. The expanded portions expand in the first direction.

In yet another embodiment, a method of forming a semiconductor device may include, but is not limited to, the following processes. A semiconductor substrate is prepared. The semiconductor substrate includes first and second regions. A first lithography process is performed. The first lithography process is applied to the first region of the semiconductor substrate. A second lithography process is performed. The second lithography process is applied to the first region and to the second region of the substrate, to form a first pattern in the first region, and to form a second pattern in the second region. The first pattern is defined by a first dimension. The first dimension is smaller than a resolution limit of lithography. The second pattern is defined by a second dimension. The second dimension is equal to or greater than the resolution limit of lithography.

In further another embodiment, a method of forming a semiconductor device may include, but is not limited to, the following processes. A semiconductor substrate is prepared. The semiconductor substrate includes first and second regions. A first lithography process is performed. The first lithography process is applied to the first region of the semiconductor substrate. A second lithography process is performed. The second lithography process is applied to the first region and to the second region of the semiconductor substrate, to form a first pattern in the first region, and to form a second pattern in the second region. The first pattern may include, but is not limited to, first and second lines that are separated by a first space. The first and second lines have a first line width. The first space has a first space width. The first line width and the first space width are smaller than a resolution limit of lithography. The second pattern may include, but is not limited to, third and fourth lines that are separated by a second space. The third and fourth lines have a second line width. The second space has a second space width. The second line width and the second space width are equal to or greater than the resolution limit of lithography.

In a moreover embodiment, a method of forming a semiconductor device may include, but is not limited to, the following processes. A semiconductor substrate is prepared. A first layer is formed over the substrate having first and second regions. A first resist pattern is formed over the first layer. A first etching process is performed using the first resist pattern as a first mask to selectively etch the first layer in the first region and form a first-original pattern in the first region. The first resist pattern is removed. The first-original pattern is processed to form a second-original pattern. The second-original pattern is defined by a first dimension that is smaller than a resolution limit of lithography. A second resist pattern is formed over the first layer having the second-original pattern. A second etching process is performed using the second resist pattern as a second mask to selectively etch the first layer in the first region and the second region, to form a first pattern in the first region, and to form a second pattern in the second region. The first pattern is defined by the first dimension. The second pattern is defined by a second dimension that is equal to or greater than the resolution limit of lithography.

In still more embodiment, a semiconductor device may include, but is not limited to, first, second, third and fourth wirings. The first, second, third and fourth wirings have first, second, third and fourth line portions and first, second, third and fourth expanded portions, respectively. The first, second, third and fourth line portions extend in parallel to each other in a first direction. The first, second, third and fourth line portions are aligned in a second direction perpendicular to the first direction. The first, second, third and fourth line portions have first, second, third and fourth line widths that are smaller than a resolution limit of lithography.

In some cases, the second wiring is adjacent to the first wiring. The third wiring is adjacent to the second wiring. The fourth wiring is adjacent to the third wiring. The first and third wirings have the first and third expanded portions at the first side respectively, and the second and fourth wirings have the second and fourth expanded portions at the second side opposite to the first side respectively.

In some cases, the first, second, third and fourth line widths are the same as each other.

In some cases, the first, second, third and fourth line widths are the same as each other. The first, second, third and fourth expanded portions are three times wider than the first, second, third and fourth line widths, respectively. The first and second expanded portions are separated by a space that is identical to the line width of the first, second, third and fourth lines. The second and third expanded portions are separated by a space that is identical to the line width of the first, second, third and fourth lines. The third and fourth expanded portions are separated by a space that is identical to the line width of the first, second, third and fourth lines.

In some cases, adjacent ones of the first, second, third and fourth wirings are arranged so that the width of the expanded portion of a first one of the adjacent ones is defined by first and second side edges parallel to each other. The first side edge of the expanded portion is aligned to a side edge of the line portion connected to the expanded portion. The second side edge of the expanded portion is aligned to a side edge of the line portion of the second one of the adjacent ones. The line portions of the adjacent ones are identical to each other. The space width between the line portions of the adjacent ones is identical to the line width of the line portions. The width of the expanded portions of the adjacent ones is three times greater than the line width or the space width.

In some cases, the semiconductor device may include, but is not limited to, fifth and sixth wirings. The fifth wiring is adjacent to the adjacent to the fourth wiring. The sixth wiring is adjacent to the adjacent to the fifth wiring. The fifth and sixth wirings have fifth and sixth line portions and fifth and sixth expanded portions, respectively. The fifth and sixth line portions extend in parallel to each other in the first direction. The fifth and sixth line portions are aligned in the second direction perpendicular to the first direction. The fifth and sixth line portions have fifth and sixth line widths that are smaller than the resolution limit of lithography. The fifth and sixth expanded portions are four times greater than the line width of the first, second, third and fourth line portions.

In yet more embodiment, a semiconductor device may include, but is not limited to, a first region and a second region. The first region may include, but is not limited to, a first pattern. The second region may include, but is not limited to, a second pattern. The first pattern is defined by a first dimension. The first dimension is smaller than a resolution limit of lithography. The second pattern is defined by a second dimension. The second dimension is equal to or greater than the resolution limit of lithography.

In an additional embodiment, a semiconductor device may include, but is not limited to, a first region and a second region. The first region may include, but is not limited to, a first pattern. The second region may include, but is not limited to, a second pattern. The first pattern is defined by a first dimension.

In some cases, the first pattern may include, but is not limited to, a first wiring pattern. The first wiring pattern may include, but is not limited to, a line portion and an expended portion. The line portion has a first width smaller than the resolution limit of lithography. The expended portion is greater in width than the line portion.

In some cases, the first-original pattern may include, but is not limited to, a plurality of first L-shaped lines. Each of the plurality of first L-shaped lines may include, but is not limited to, a line portion and an expanded portion. The first L-shaped lines are aligned at a constant pitch in a first direction. The first direction is perpendicular to a second direction along which the line portions extend. The expanded portions expand in the first direction. The expanded portion of each of the first L-shaped lines is positioned outside, in the second direction, the line portion of an adjacent one of the first L-shaped lines. The expanded portions of two adjacent ones of the first L-shaped lines are positioned at opposite sides in the second direction.

In some cases, the first region may be a memory cell region, and the second region may be a peripheral circuit region.

In some cases, the first pattern may include, but is not limited to, at least one of a word line pattern and a bit line pattern.

In some cases, each of the plurality of third L-shaped lines may include, but is not limited to, a line portion and an expanded portion. The line portion has a first width as the first dimension. The first width is smaller than the resolution limit of lithography. The expanded portion has a second width that is three times wider than the first width. The third L-shaped lines are aligned at a constant pitch in a first direction. The first direction is perpendicular to a second direction along which the line portions extend. The first constant pitch is two times greater than the first width. The expanded portions expand in the first direction.

In a further additional embodiment, a semiconductor device may include, but is not limited to, a first region and a second region. The first region may include, but is not limited to, a first pattern. The second region may include, but is not limited to, a second pattern. The first pattern may include, but is not limited to, first and second lines that are separated by a first space. The first and second lines have a first line width. The first space has a first space width. The first line width and the first space width are smaller than a resolution limit of lithography. The second pattern may include, but is not limited to, third and fourth lines that are separated by a second space. The third and fourth lines have a second line width. The second space has a second space width. The second line width and the second space width are equal to or greater than the resolution limit of lithography.

In some cases, the first region may be a memory cell region, and the second region may be a peripheral circuit region.

In some cases, the first pattern may include, but is not limited to, at least one of a word line pattern and a bit line pattern.

In a furthermore additional embodiment, a data processing system may include, but is not limited to, the semiconductor device described above.

### EMBODIMENTS

An embodiment of the invention will be described in detail with reference to the accompanying drawings.

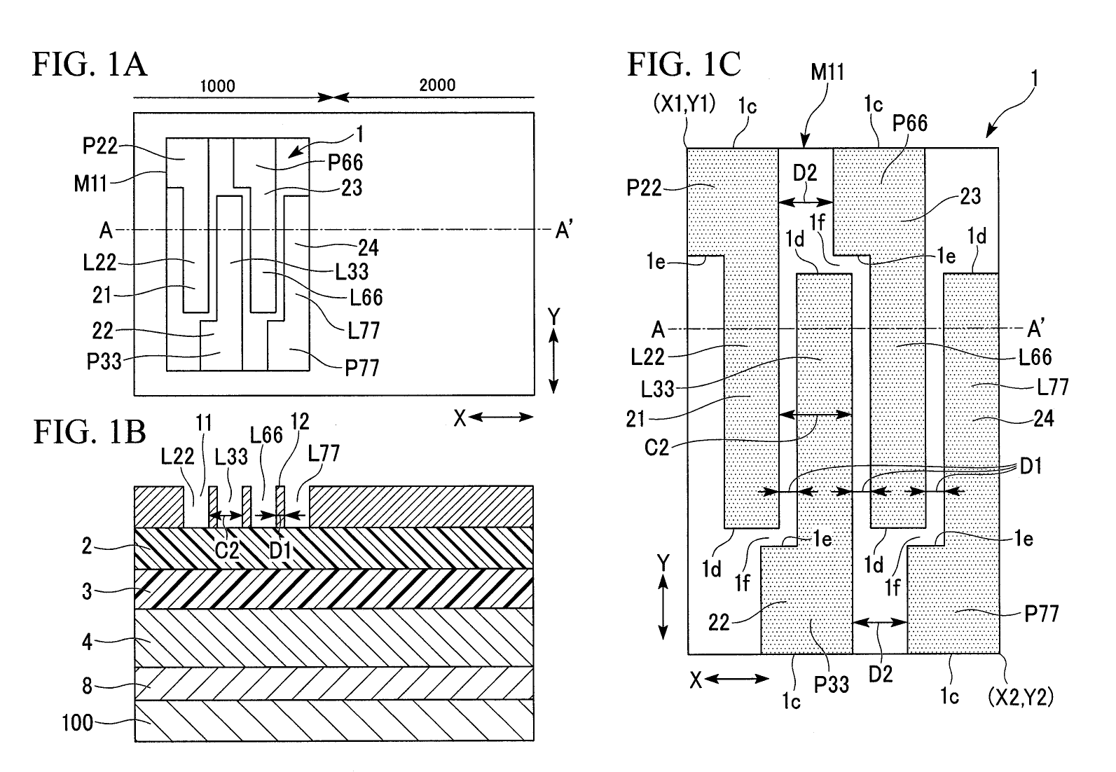

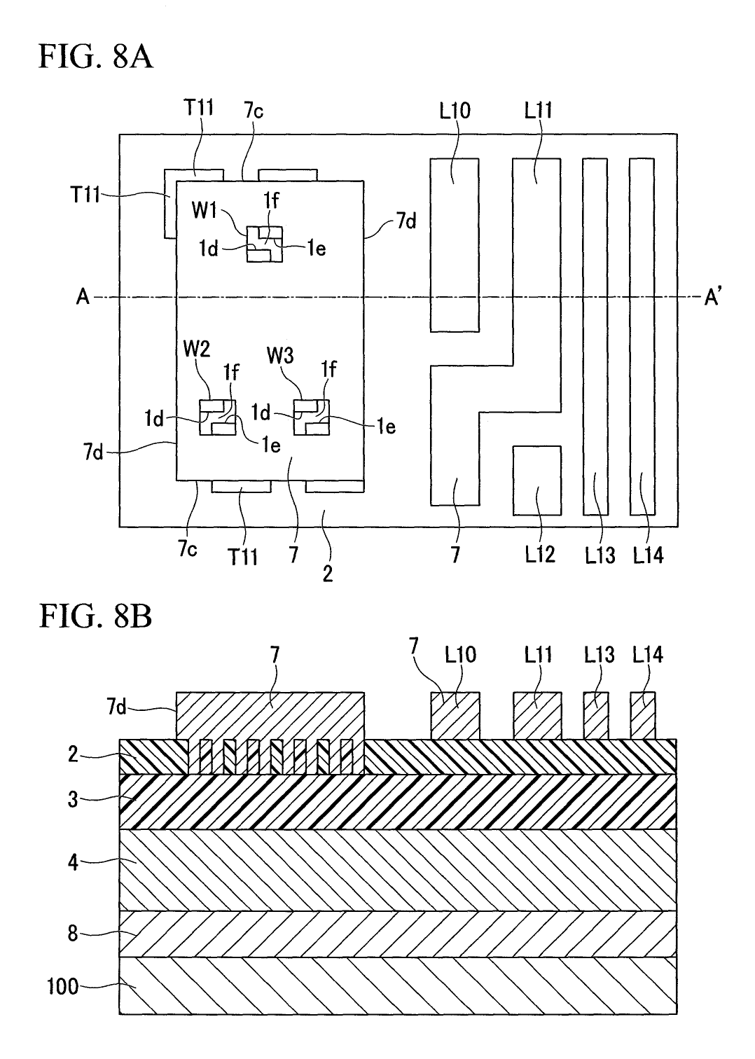

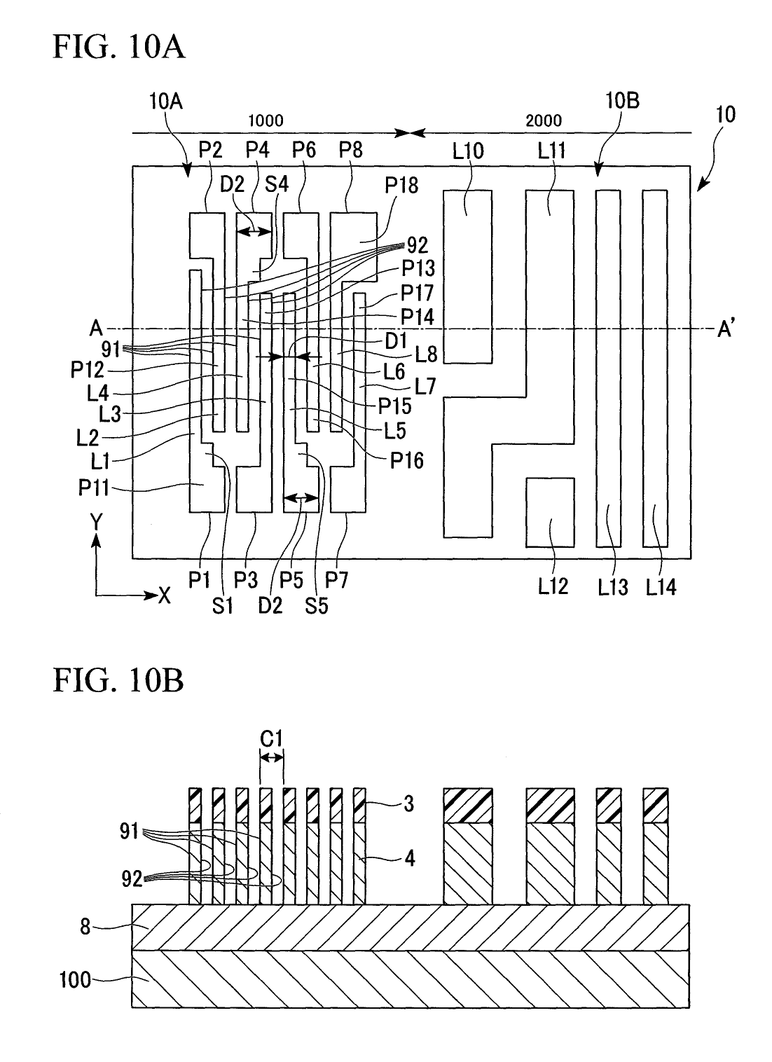

FIGS. 1A to 10B are views illustrating an example of a method of forming a wiring pattern and a method of manufacturing a semiconductor device of the embodiment of the invention. FIGS. 10A and 10B are enlarged views showing some wiring patterns formed in a semiconductor device. FIG. 10A is a plan view, and FIG. 10B is a sectional view taken along the line A-A′ line shown in FIG. 10A. FIGS. 1A to 7B, 9A, and 9B are views illustrating an example of the method of forming a wiring pattern shown in FIGS. 10A and 10B. FIGS. 1A to 7B and 9A are plan views corresponding to FIG. 10A. FIGS. 1A to 7B and 9B are sectional views taken along the line A-A′ shown in FIGS. 1A to 7B and 9A. FIG. 1C is an enlarged view illustrating the details of FIG. 1A. FIGS. 8A and 8B are views illustrating an example of the method of forming a wiring pattern shown in FIGS. 10A and 10B. FIG. 8A is a view illustrating the shape of a second photoresist pattern and is also a plan view corresponding to FIG. 10A showing a state where the second photoresist pattern overlaps an original second pattern. In addition, FIG. 8B is a sectional view taken along the line A-A′ shown in FIG. 8A and is also a view showing a state where the second photoresist pattern is formed on a second mask layer, a third mask layer, and a first mask layer.

The left half of the illustrations in each of the drawings of FIGS. 1A to 10B except for FIG. 1C shows a memory cell region 1000 as a first wiring pattern forming region, and right halves show a peripheral circuit region 2000 as a second wiring pattern forming region. In the present embodiment, for the sake of convenience, the right sides of the illustrations in FIGS. 1A to 10B are defined as the second wiring pattern forming region which becomes the peripheral circuit region 2000 shown in FIG. 10A.

In addition, in the invention, the second wiring pattern forming region is not limited to the example shown in FIGS. 1A to 10B, and all regions other than the first wiring pattern forming region may be regarded as the second wiring pattern forming region. Thus, there is no limitation on the region where the second wiring pattern forming region is formed.

In the present embodiment, a memory semiconductor device, such as a DRAM (Dynamic Random Access Memory) or a NAND flash memory provided in a data processing system, will be described as an example. In addition, each drawing is a schematic view. For example, the length of a wiring line which extends in a Y direction in a memory cell is in a range of several micrometers to several millimeters, but it is reduced for convenience of explanation.

### Wiring Pattern:

As shown in FIGS. 10A and 10B, a wiring pattern 10 of the present embodiment has a protruding shape and includes a first wiring pattern 10A and a second wiring pattern 10B.

The second wiring pattern 10B shown in FIG. 10A is formed using a normal lithography process. The second wiring pattern 10B includes wiring lines L10 to L14, which are a plurality of normal patterns with dimensions equal to or more than the resolution limit of lithography. The second wiring pattern 10B may have an optional pattern shape without being limited to the example shown in FIG. 10A.

The first wiring pattern 10A is formed using an SADP method. The first wiring pattern 10A includes wiring lines P11 to P18, which are a plurality of patterns with dimensions less than the resolution limit of lithography. In the present embodiment, the first wiring pattern 10A includes a wiring unit 11 formed by the four wiring lines P14, P13, P15, and P16. Although the wiring unit 11 is formed by the wiring lines P14, P13, P15, and P16 as shown in FIG. 10A, the wiring unit 11 may also be formed by four adjacent wiring lines selected arbitrarily from the wiring lines P11 to P18 included in the first wiring pattern 10A. For example, the wiring unit 11 may be formed by the wiring lines P11, P12, P14, and P13.

In addition, the number of wiring lines included in the first wiring pattern 10A is not limited to the example shown in FIG. 10A. For example, a plurality of arrangements obtained by repeatedly disposing the wiring unit 11 in the X direction and at equal distances in the memory cell region (first wiring pattern forming region) 1000 are possible as necessary. Usually, tens to several thousands of wiring lines are arrayed in a memory cell region of a semiconductor device.

The wiring lines P11 to P18 included in the first wiring pattern 10A are formed by lines L1 to L8 and pads P1 to P8 disposed at the ends of the lines L1 to L8 near the outer periphery of the first wiring pattern forming region (region partitioned by M11 in FIGS. 1A to 1C which will be described later), respectively. Each of the pads P1 to P8 is formed by increasing the width of one end of each of the lines L1 to L8 in only one direction, so that the pads P1 to P8 can function as a lead-out pad contacted with an upper-layer wiring line.

In FIG. 10A, the pad P1 located at the leftmost end and the pad P2 located at the second from the left, the pads P3 and P4 located at the inside, the pads P5 and P6 located at the inside, and the pad P7 located at the rightmost end and the pad P8 located at the second from the right form pairs. The pads which form each pair are formed at the opposite ends of the lines. Moreover, for example, the pads P2 and P4, the pads P3 and P5, or the pads P6 and P8 are not formed at the opposite ends. That is, assuming that the wiring line P11 located at the leftmost end in FIG. 10A is a reference, pads are formed at the ends of opposite lines of the wiring line P11 and the wiring line P12 adjacent to the wiring line P11.

In addition, as shown in FIG. 10A, the pad P1 widens inward (direction toward the middle of the first wiring pattern forming region M11) from the line L1, and the pad P2 widens outward (direction toward the outside of the first wiring pattern forming region M11) from the line L2. In addition, the pad P4 widens inward from the line L4, and the pad P2 widens in the opposite direction to the widening direction of the pad P4. That is, in the wiring lines P11 to P18 formed in the memory cell region 1000, the widening directions of pads connected to two arbitrary wiring lines adjacent to each other are necessarily opposite directions.

Moreover, in a range of the width D2 of an arbitrary pad which forms each of the wiring lines P11 to P18, a line connected to the pad and a line connected to another pad are included in a region which extends in the extension direction of each line (Y direction in FIG. 10A). These two lines are separated from each other with a space, which has the same width as each line, therebetween. That is, a distance between the two lines is equal to the width of each of the two lines. For example, with regard to the pad P5, two lines of the line L5 connected to the pad P5 and the line L6 connected to the pad P6 are included in a region extending upward along the extension direction of each line, which is a range of the width D2, and the lines L5 and L6 are separated from each other with a space, which has the same width as each of the lines L5 and L6, therebetween. Accordingly, the width of each of the pads P1 to P7 is three times the width of each of the lines L1 to L8.

In addition, two arbitrary adjacent pads are separated from each other with a space, which has the same width as each line, therebetween, and the distance between adjacent pads in the wiring lines P11 to P18 is equal to the width of each line.

In addition, in the first wiring line P11 and the wiring lines P14 and P15 which are formed sequentially from the first wiring line P11 with another wiring line therebetween, steps S1, S4, and S5 are formed at connecting portions between the lines and the pads. In the example shown in FIG. 10A, only eight wiring lines are formed. However, for example, when twelve wiring lines are formed by adding one wiring unit 11 between the wiring lines P16 and P18, steps are formed at connecting portions between lines and pads in wiring lines disposed at the seventh and ninth from the left in FIGS. 10A and 10B.

Moreover, in the wiring pattern 10 shown in FIG. 10A, the widths D1 of the lines L1 to L8 which form the wiring lines P11 to P18 of the first wiring pattern 10A are equal to each other, and the width D1 is ½ of the resolution limit dimension. Accordingly, the pitch of line and space of each wiring line (line) is equal to the resolution limit dimension of lithography. In addition, the widths D2 of the pads P1 to P7 of the first wiring pattern 10A are equal, and width D2 is three times the width D1 of each line. Accordingly, the width D2 is larger than the resolution limit dimension.

Moreover, in the present embodiment, pads with the same position (upper or lower end) and widening direction (inside or outside) with respect to the lines are arrayed every four wiring lines included in the first wiring pattern 10A. That is, all the pads which form four adjacent wiring lines selected arbitrarily are different in at least either the position or the widening direction with respect to each line. For example, with regard to the four wiring lines P14, P13, P15, and P16 provided in the middle of the first wiring pattern 10A in the X direction, the pads P4 and P6 corresponding to the lines L4 and L6 in the outer wiring lines P14 and P16 are located at the upper ends of the lines and the widening directions thereof are opposite, and the pads P3 and P5 corresponding to the lines L3 and L5 in the inner wiring lines P13 and P15 are located at the lower ends of the lines and the widening directions thereof are opposite. With regard to the wiring line P18 adjacent to the outer side of the wiring line P16, the position and the widening direction of the pad P8 with respect to the line are the same as those of the pad P4. Similarly, for example, the position and the widening direction of the pad P1 with respect to the line are the same as those of the pad P5 with regard to the wiring line P11, and the position and the widening direction of the pad P2 with respect to the line are the same as those of the pad P6 with regard to the wiring line P12.

With regard to the wiring lines P14, P13, P15, and P16, the wiring unit 11 configured to include the four adjacent wiring lines P14, P13, P15, and P16 will be described more specifically.

As shown in FIG. 10A, the wiring lines P14, P13, P15, and P16 include the lines IA, L3, L5 and L6, which extend in the first direction (Y direction) with a width less than the resolution limit defined by first and second side surfaces 91 and 92, and the pads P4, P3, P5, and P6 disposed at the ends of the lines L4, L3, L5 and L6, respectively.

The wiring line P14 (first wiring line) includes the first line L4 and the first pad P4, which is disposed at one end (upper end) of the first line L4 and widens toward the second side surface 92.

The wiring line P13 (second wiring line) includes the second line L3 adjacent to the first line L4 and the second pad P3, which is disposed at the other end (lower end) of the second line L3 and widens toward the first side surface 91.

The wiring line P15 (third wiring line) includes the third line L5 adjacent to the second line L3 and the third pad P5, which is disposed at the other end (lower end) of the third line L5 and widens toward the second side surface 92.

The wiring line P16 (fourth wiring line) includes the fourth line L6 adjacent to the third line L5 and the fourth pad P6, which is disposed at the one end (upper end) of the fourth line L6 and widens toward the first side surface 91.

In the present embodiment, as shown in FIG. 10A, two wiring lines (edge wiring lines) P18 and P17 are provided which are adjacent to the wiring line P16 of the wiring unit 11 and which include the lines L8 and L7, which extend in the first direction (Y direction) with a width less than the resolution limit defined by the first and second side surfaces 91 and 92, and the pads P8 and P7 disposed at the ends of the lines L8 and L7, respectively. The two wiring lines (edge wiring lines) P18 and P17 form an X-direction edge portion of the first wiring pattern 10A.

The wiring line P18 (fifth wiring line) is disposed at the first from the right end in FIG. 10A, among the plurality of wiring lines P11 to P18 included in the first wiring pattern 10A. The wiring line P18 (fifth wiring line) includes the fifth line L8 adjacent to the fourth line L6 and the fifth pad P8, which is disposed at one end (upper end) of the fifth line L8 and widens toward the second side surface 92. The pad P8 which forms the wiring line P18 is larger than the other pads P1 to P7 horizontally and vertically, and the width of the pad P8 is four times the width D1 of the line of each wiring line.

The wiring line P17 (sixth wiring line) is disposed at the rightmost end in FIG. 10A, among the plurality of wiring lines P11 to P18 included in the first wiring pattern 10A. The wiring line P17 (sixth wiring line) includes the sixth line L7 adjacent to the fifth line L8 and the sixth pad P7, which is disposed at the other end (lower end) of the sixth line L7 and widens toward the first side surface 91.

In the present embodiment, in the wiring line P11 disposed at the leftmost end in FIG. 10A among the plurality of wiring lines P11 to P18 included in the first wiring pattern 10A, the end of the line L1 not connected to the pad P1 is located to extend to the outer side more than the ends of the lines of the other wiring lines (L3, L5, L7).

In the present embodiment, the wiring pattern 10 is formed on an insulating layer 8, such as a silicon oxide film formed on a semiconductor substrate 100, as shown in FIG. 10B. Each of the wiring lines P11 to P18 and L10 to L14 included in the wiring pattern 10 has a structure where a first mask layer 3, such as a silicon nitride film, is laminated on a wiring layer 4, such as a tungsten film. Although tungsten is mentioned as an example of a material of the wiring layer 4 in the present embodiment, other metals or metal compounds, silicon containing impurities, and the like may also be applied as materials of the wiring layer 4.

The wiring lines P11 to P18 and L10 to L14 included in the wiring pattern 10 may be used as word lines or bit lines of a memory semiconductor device. When using the wiring lines P11 to P18 and L10 to L14 as word lines, the insulating layer 8 is used as a gate insulating layer. When using the wiring lines P11 to P18 and L10 to L14 as bit lines, the insulating layer 8 is used as an interlayer insulating layer for electrical isolation from a lower-layer wiring line.

### Data-Processing-System:

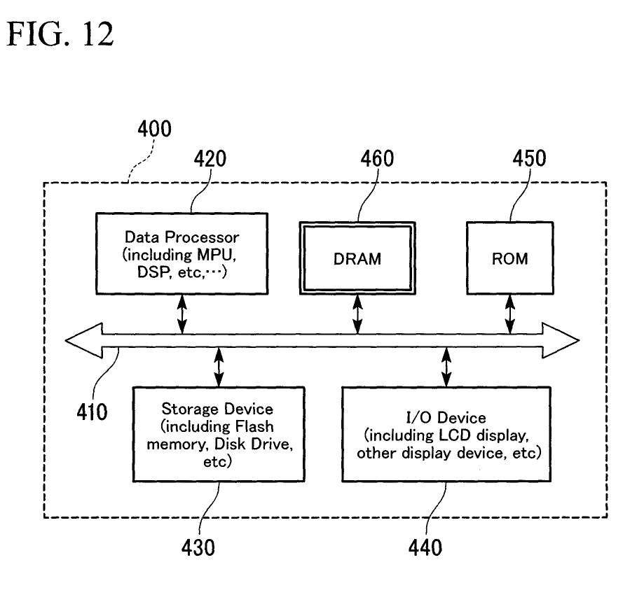

FIG. 12 is a block diagram showing the configuration of a data processing system 400 using a memory semiconductor device according to a preferred embodiment of the invention, and shows a case where the memory semiconductor device according to the present embodiment is a DRAM.

The data processing system 400 shown in FIG. 12 has a configuration where a data processor 420 and a DRAM 460 according to the present embodiment are connected to each other through a system bus 410. Examples of the data processor 420 include a microprocessor (MPU) and a digital signal processor (DSP), but it is not limited thereto. In FIG. 12, the data processor 420 and the DRAM 460 are connected to each other through the system bus 410 for the sake of simplicity. However, the data processor 420 and the DRAM 460 may be connected to each other through a local bus without the system bus 410.

In addition, although only one system bus 410 is shown in FIG. 12 for the sake of simplicity, it may also be provided in a serial or parallel manner through a connector or the like when necessary.

In addition, a storage device 430, an I/O device 440, and a ROM 450 are connected to the system bus 410 in the data processing system 400 shown in FIG. 12. However, these are not necessarily required components.

A hard disk drive, an optical disk drive, a flash memory, and the like may be mentioned as the storage device 430. In addition, display devices, such as a liquid crystal display device, and input devices, such as a keyboard and a mouse, may be mentioned as the I/O device 440. In addition, the I/O device 440 may be either an input device or an output device. Although each component shown in FIG. 12 is shown singly for the sake of simplicity, it is not limited thereto. One or two or more components may be provided in groups.

### Wiring Pattern Forming Method:

In the present embodiment, a wiring pattern forming method will be described by way of a method of forming the wiring pattern 10 shown in FIGS. 10A and 10B which has the memory cell region (first wiring pattern forming region) 1000, in which the first wiring pattern 10A including the plurality of wiring lines P11 to P18 with dimensions less than the resolution limit is provided, and the peripheral circuit region (second wiring pattern forming region) 2000, in which the second wiring pattern 10B including the plurality of wiring lines L10 to L15 with dimensions equal to or more than the resolution limit is provided.

In the wiring pattern forming method of the present embodiment, the first wiring pattern 10A is formed by performing a first lithography process and then performing a second lithography process, and the second wiring pattern 10B is formed simultaneously with the first wiring pattern 10A by performing the second lithography process.

In the present embodiment, the wiring layer 4 such as a tungsten film, the first mask layer 3 such as a silicon nitride film, and the second mask layer 2 (lower material layer) such as a silicon film are formed sequentially on the insulating layer 8, such as a silicon oxide film formed on the semiconductor substrate 100, before performing the first lithography process.

A silicon layer 2 serving as the second mask layer 2 may be formed using an LP-CVD method in which monosilane is used as source gas and the film formation temperature is set to 530° C., for example. The silicon film formed at this film formation temperature has an amorphous state. Disilane (Si₂H₆) may be used as source gas. Disilane is excellent in reactivity and makes it possible to increase the deposition rate compared with monosilane.

### First Lithography Process:

Then, the first lithography process is performed. In the first lithography process, as shown in FIG. 1A, a first photoresist pattern 1 is first formed in the memory cell region (first wiring pattern forming region) 1000. As shown in the sectional view of FIG. 1B, the first photoresist pattern 1 is a groove pattern formed by a groove 11a and a space 12a. FIG. 1C is an enlarged view of the first photoresist pattern 1.

As shown in FIG. 1A, the first photoresist pattern 1 has a plurality of first L patterns 21, 22, 23, and 24 which are L shaped grooves in plan view. Here, the L pattern collectively refers to up-and-down reversed L patterns and left-and-right reversed L patterns, the directions of which are reversed vertically and horizontally.

The first L patterns have lines L22, L33, L66, and L77 and pads P22, P33, P66, and P77 obtained by increasing the width of one end of each line in only one direction. The pitch C2 of line and space of each of the lines L22, L33, L66, and L77 shown in FIG. 1B is twice the pitch C1 of line and space of each of the lines L1 to L8 of the wiring lines P11 to P18 included in the first wiring pattern 10A shown in FIG. 10B. Accordingly, the pitch C2 of the lines L22, L33, L66, and L77 is 4 times the width D1 of the lines L1 to L8 shown in FIG. 10B.

Moreover, in the present embodiment, the first photoresist pattern 1 is set to have four first L patterns in the example shown in FIGS. 1A to 1C in order to make it correspond to the shape of the first wiring pattern 10A shown in FIGS. 10A and 10B. However, the number of first L patterns included in the first photoresist pattern 1 is not limited to four, and is determined according to the shape of the first wiring pattern 10A to be formed.

Hereinafter, the shape of the first photoresist pattern 1 will be described in detail using FIG. 1C.

In the first photoresist pattern 1, first L patterns adjacent to each other with another L pattern interposed therebetween (in FIG. 1C, the first L patterns 21 and 23 or the first L patterns 22 and 24) have the same shape. Regarding the arrangement of the first L patterns 21 to 24, the first L patterns adjacent to each other are up-and-down reversed patterns. In addition, another first L pattern is shifted from adjacent one first L pattern in the X direction by the pitch C2 of lines, and the first L patterns are shifted from each other in the Y direction with at least a gap equal to or more than the width D1 of each line, which is shown in FIG. 10B, such that another first L pattern does not overlap the one adjacent first L pattern. Here, the Y direction is a longitudinal direction of each line, and the X direction is a direction perpendicular to the Y direction.

The first L patterns 21 to 24 are arrayed repeatedly and continuously in the X direction at equal distances therebetween. In addition, each of the pads P33, P66, and P77 is disposed at the outer side in the Y direction such that one side 1e thereof is distant from an end 1d of each of the opposite lines L22, L33, and L66 by at least the width D1 of each line. For the pad P22 located at the leftmost end in FIG. 1C, an adjacent line does not exist in a step of forming the first photoresist pattern 1.

In addition, pads of the adjacent first L patterns are disposed at the ends of corresponding lines which are different ends in the Y direction. In addition, the increasing directions of the widths of the lines L22, L33, L66, and L77 in pads of all first L patterns 21 to 24 are equal. In the present embodiment, all of the widths increase to the left in FIG. 1C. However, all widths may increase to the right. Thus, in the pattern forming method of the embodiment, disposing the adjacent first L patterns as up-and-down reversed patterns and increasing the widths of pads in the same direction are essential conditions.

More specifically, for example, with regard to the first L pattern 22 located at the second from the left in FIG. 1A among the first L patterns 21 to 24, the pad P33 is located at the outer side in the Y direction than the other ends 1d of the lines L22 and L66 of the first L patterns 21 and 23 adjacent to the first L pattern 22. In addition, the end 1d of the line L22 and the one side 1e of the pad P33, which is located opposite the end 1d, are separated from each other with a distance 1f equal to or more than at least the width D1 of the line. In addition, the pad P33 is disposed at the lower end of the line L33 in FIG. 1C, but the pads P22 and P66 of the adjacent first L patterns 21 and 23 are disposed at the upper ends of the lines L22 and L66 in FIG. 1C. That is, the pad of the first L pattern 22 is disposed at the end which is a different position in the Y direction from the pads of the first L patterns 21 and 23.

Moreover, in the present embodiment, the width of each of the lines L1 to L8 of the wiring lines P11 to P18 included in the first wiring pattern 10A shown in FIGS. 10A and 10B is set to the distance D1 between the adjacent first L patterns in the lines of the first L patterns.

In the present embodiment, the distance between adjacent first L patterns is already set to be less than the resolution limit in the step where the first photoresist pattern 1 is formed, and the first photoresist pattern 1 may be formed using a photoresist slimming method. In addition, the dimension of the first photoresist pattern 1 may be finely adjusted in a process of etching the second mask layer 2 which is the next process.

Moreover, in the present embodiment, the distance D2 between a pad (for example, the pad P22) of one first L pattern and a pad (for example, the pad P66) of another first L pattern, which is adjacent to the pad (for example, the pad P22) with still another first L pattern interposed therebetween, is set to the width D2 of the pad (for example, the pad P4) of each of the wiring lines P11 to P18 included in the first wiring pattern 10A shown in FIGS. 10A and 10B.

In the present embodiment, the first pattern forming region is a rectangular region indicated by reference numeral M11 in FIG. 1A. As shown in FIG. 1C, the first pattern forming region M11 is a rectangular region including an upper left apex (X1, Y1) of the pad P22 in the first L pattern 21, which is located at the leftmost end, and a lower right apex (X2, Y2) of the pad P77 in the first L pattern 24, which is located at the rightmost end. In the present embodiment, the case where there are four first L patterns is illustrated, but the same is true for the case where there are hundreds of first L patterns, for example.

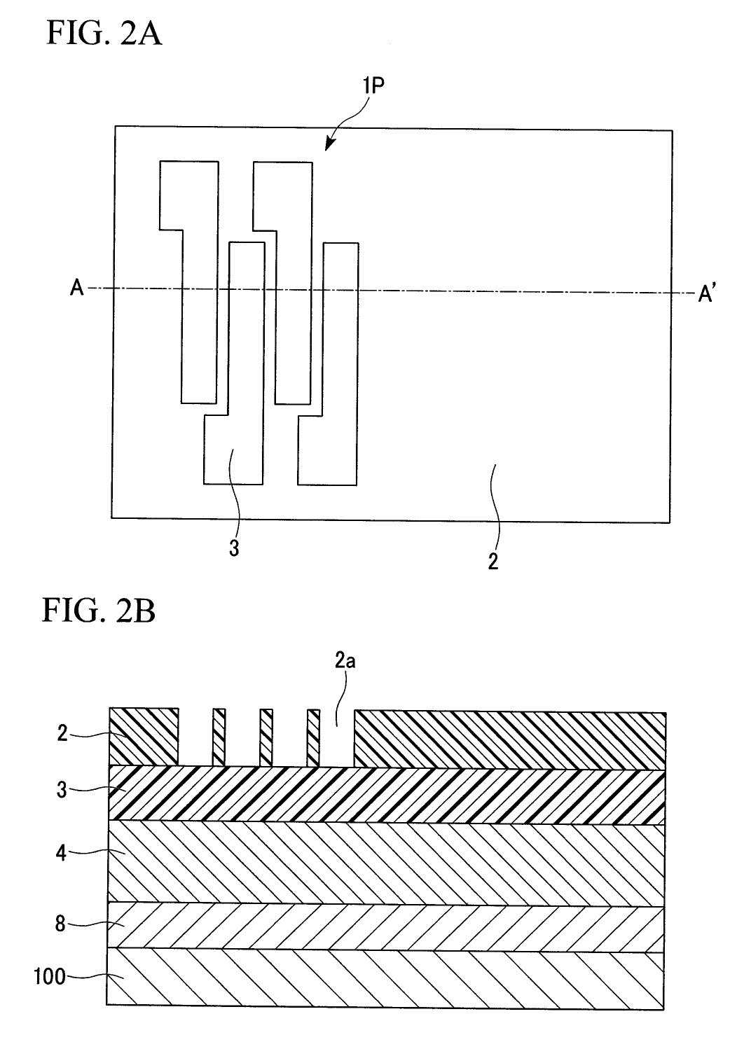

Then, as shown in FIGS. 2A and 2B, the second mask layer 2 (lower material layer) is etched by a dry etching method or the like using the first photoresist pattern 1 as a mask. As a result, a first original pattern 1P is formed in the second mask layer 2 (first etching process) as shown in FIG. 2B. Then, the first photoresist pattern 1 is removed using a wet etching method or the like. As a result, the first original pattern 1P having four second L patterns formed by second mask grooves 2a is formed as shown in FIGS. 2A and 2B, and the first mask layer 3 is exposed on the bottom surface of the second mask groove 2a as shown in FIG. 2B. In addition, the shape of the second L pattern is almost the same as the shape of the first L pattern of the first photoresist pattern 1 used as a mask. However, they are not completely the same due to processing error when etching the second mask layer 2 and fine adjustment of the distance between the second mask grooves 2a. Accordingly, the first original pattern 1P transferred to the second mask layer 2 is distinguished as a second L pattern.

Next, a second original pattern with a dimension less than the resolution limit is formed by processing the second mask layer 2 in which the first original pattern is formed.

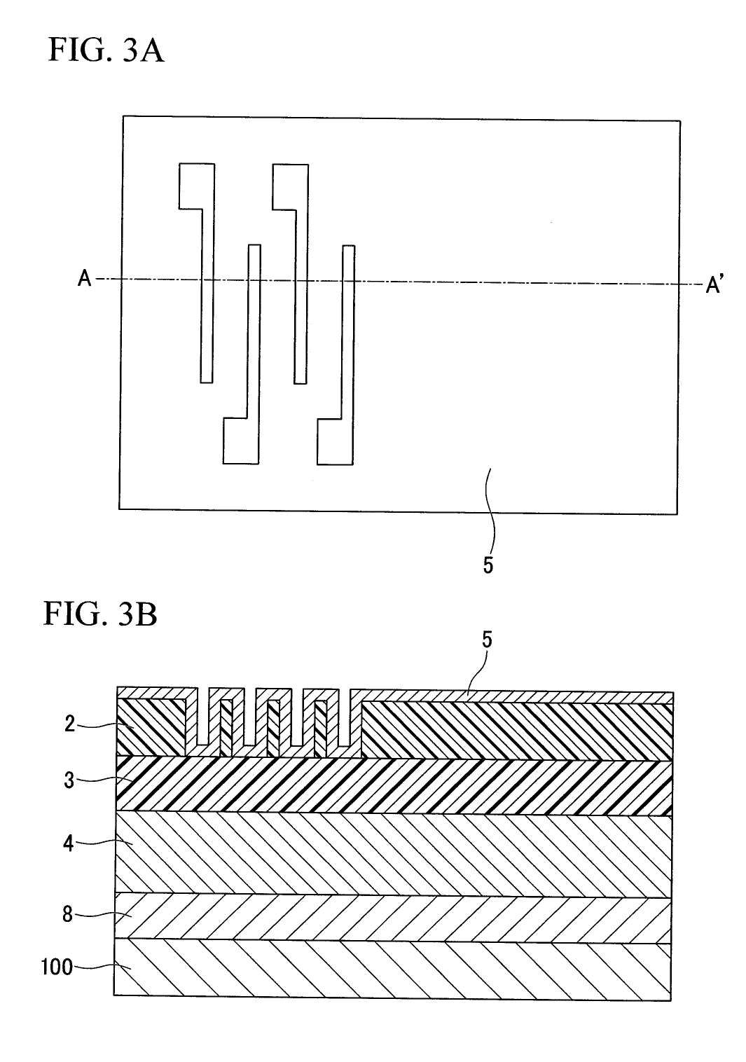

In the process of forming the second original pattern, as shown in FIGS. 3A and 3B, a sidewall layer 5 made of a different material from the second mask layer 2 is formed on the whole surface in a predetermined thickness in which the line of the second mask groove 2a is not embedded.

In the embodiment, since the thickness control of the sidewall layer 5 largely influences the final pattern formation, it is preferable to form the sidewall layer 5 using an LP-CVD (Low Pressure-Chemical Vapor Deposition) method which is good in terms of step coverage and is excellent in terms of thickness control. In addition, the sidewall layer 5 needs to be formed of a material which is different in etching rate from the second mask layer 2. For example, when a silicon film is used as the second mask layer 2, a silicon oxide film may be used as the sidewall layer 5. The silicon oxide film which is good in terms of step coverage and film thickness control may be formed using the LP-CVD method in which monosilane (SiH₄) is used as source gas and nitrous oxide (N₂O) is used as oxidation gas under the conditions of the temperature range of 700° C. to 800° C. and the pressure range of 0.1 Torr to 2.0 Torr. If dichlorosilane (SiH₂Cl₂) is used as source gas, the thickness of the sidewall layer 5 can be controlled more precisely. Moreover, using, as a method of forming a silicon oxide film, an ALD (Atomic Layer Deposition) method of forming one atomic layer at a time by repeating the supply and exhausting of source gas and the supply and exhausting of oxidation gas is also effective for improving the film thickness control efficiency. Since a film can be formed at a low temperature of about 400° C. using the ALD method, the thermal load in a manufacturing process is reduced. Accordingly, deterioration of the characteristics of transistors already formed on the semiconductor substrate surface can be suppressed. When forming a silicon oxide film using the ALD method, organic source gas selected from dimethylamino silane (H₃Si(N(CH₃)₂)), bis(dimethylamino) silane (H₂Si(N(CH₃)₂)₂), tris(dimethylamino) silane (HSi(N(CH₃)₂)₃), tetrakis(dimethylamino) silane (Si(N(CH₃)₂)₄), and the like may be used as source gas, and ozone (O₃), vapor (H₂O), oxygen radicals, and the like may be used as oxidation gas.

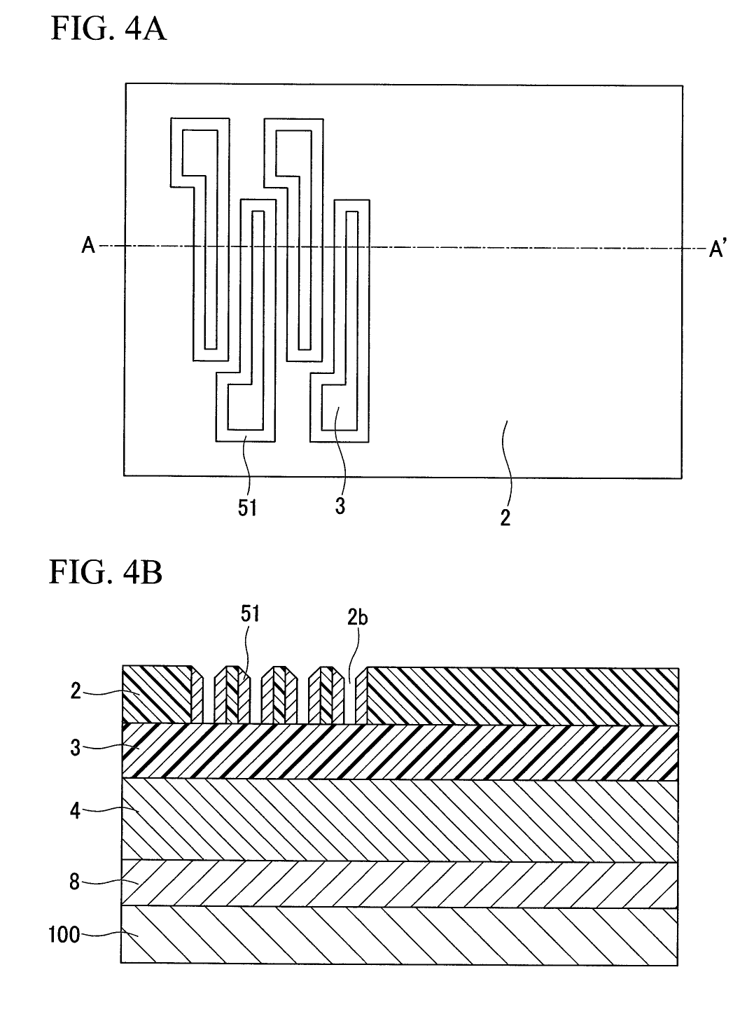

Then, as shown in FIGS. 4A and 4B, a sidewall 51 is formed on the side wall of the second mask groove 2a by etching back the sidewall layer 5 using the dry etching method or the like. As a result, a part of the second mask groove 2a is embedded in FIG. 4B as indicated by reference numeral 2b. In the present embodiment, the thickness of the sidewall 51 can be precisely controlled since it is determined by the thickness of the sidewall layer 5.

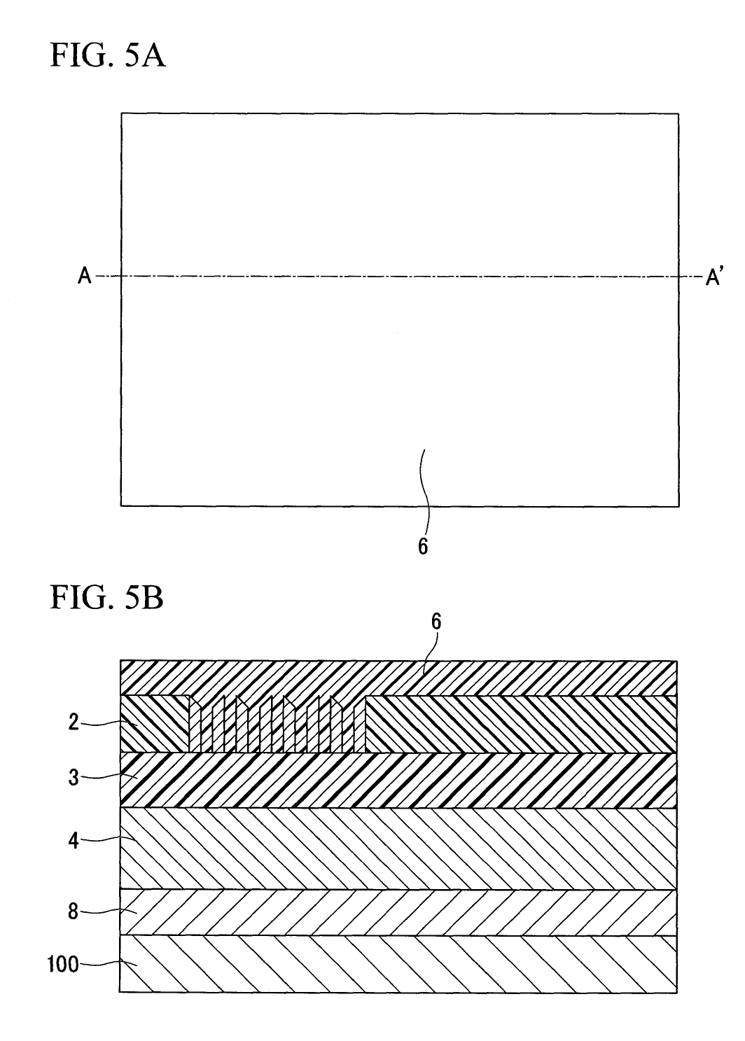

After forming the sidewall 51 as described above, a third mask layer 6 made of the same material as the second mask layer 2a is formed in such a thickness that the entire second mask groove 2a is embedded, as shown in FIGS. 5A and 5B. When the second mask layer 2 is a silicon film, it is preferable to form the third mask layer 6, such as a silicon film, using a CVD (Chemical Vapor Deposition) method or the like. As a silicon film which forms the third mask layer 6, a polycrystalline silicon film (polysilicon film) or an amorphous silicon film may be used. The amorphous silicon film is more preferable than the polycrystalline silicon film since the surface flatness after film formation is good and a processing variation caused by the crystal grain boundary can be suppressed.

Moreover, although the sectional view of a line of the second mask groove 2a is shown in FIG. 5B, the third mask layer 6 is formed so as to be completely embedded in a pad connected to the line as well as the line of the second mask groove 2a.

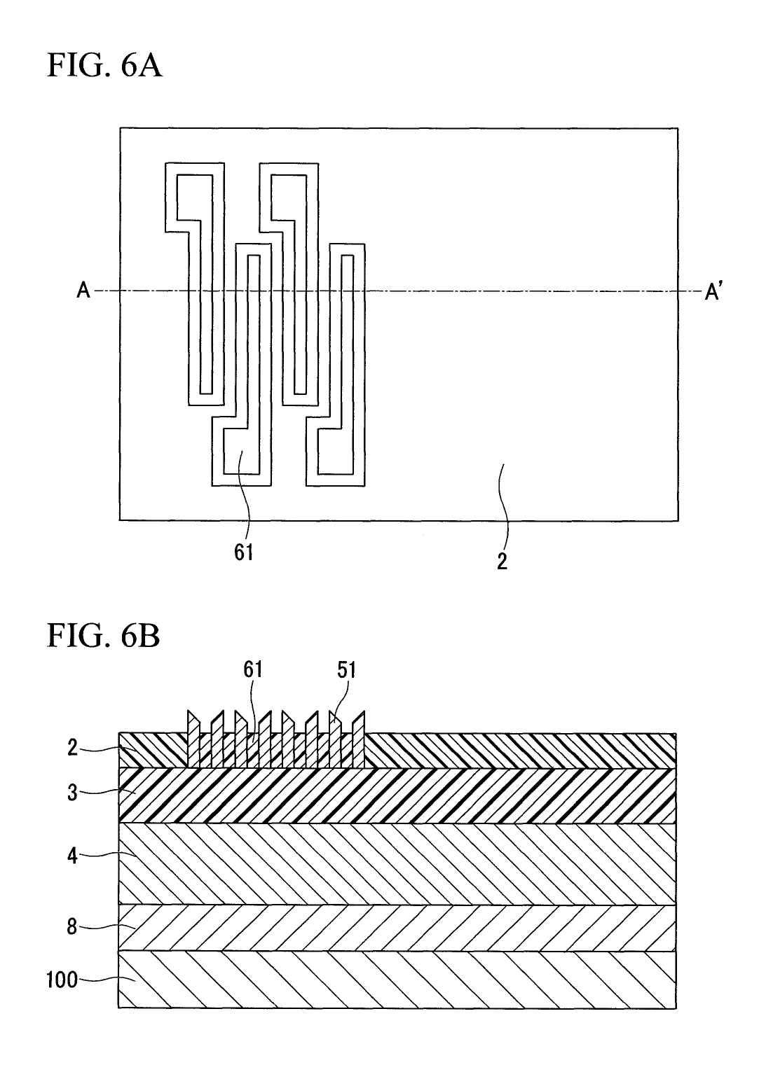

Then, as shown in FIGS. 6A and 6B, the third mask layer 6 and the second mask layer 2 are etched back using the dry etching method or the like so that an upper part of the sidewall 51 is exposed. As a result, the upper part of the sidewall 51 is exposed and at the same time, a third mask layer 61 embedded in a region surrounded by the sidewall 51 is formed. In the present embodiment, since the third mask layer 6 and the second mask layer 2 are formed of the same material, the etching rate of the third mask layer 6 and the etching rate of the second mask layer 2 can be made equal. Accordingly, as shown in FIG. 6B, only the upper part of the sidewall 51 can be exposed by making equal the surface position of the embedded third mask layer 61 and the surface position of the second mask layer 2 after etchback.

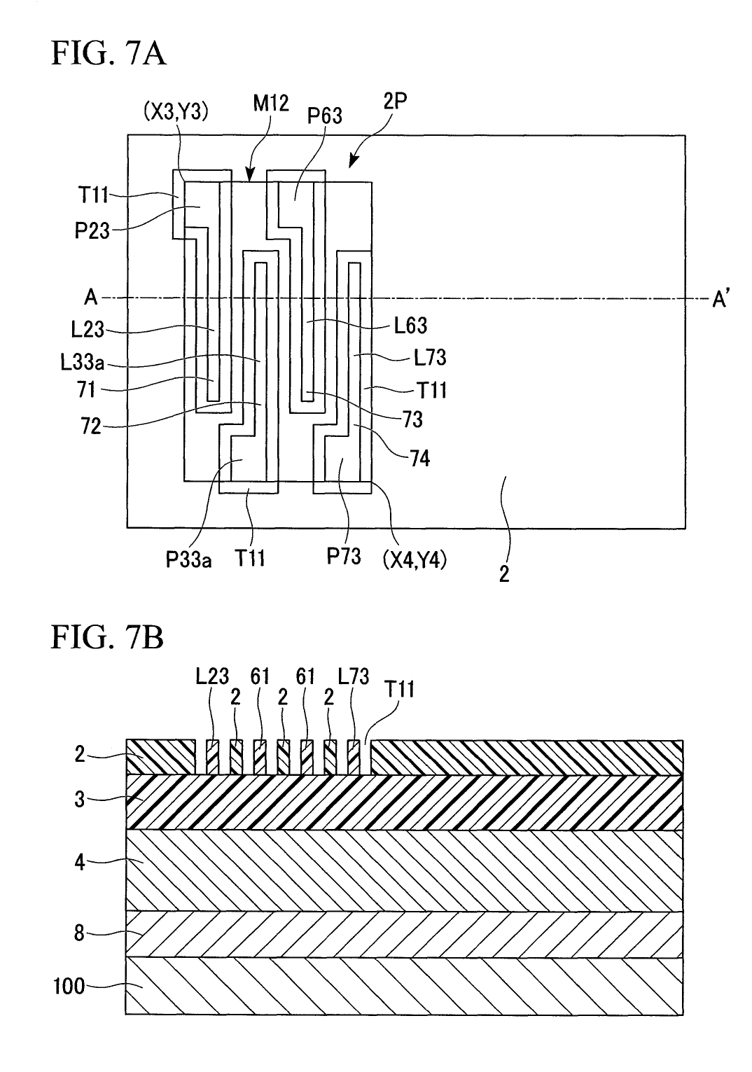

Then, a trench T11 interposed between the third mask layer 61 and the second mask layer 2 is formed as shown in FIGS. 7A and 7B by selectively removing the sidewall 51, the upper part of which has been exposed, by the wet etching method using a solution containing fluoric acid (HF). As a result, a second original pattern 2P, which has the trench T11 inside along the outer periphery of the first original pattern 1P, is formed.

As shown in FIG. 7A, the second original pattern 2P has four third L patterns 71, 72, 73, and 74. The four third L patterns 71, 72, 73, and 74 are formed by the third mask layer 61 and include lines L23, L33a, L63, and L73, each of which has a width less than the resolution limit, and pads P23, P33a, P63, and P73 connected to the lines, respectively. The four third L patterns 71, 72, 73, and 74 are formed by reducing the entire four second L patterns of the first original pattern 1P, which is shown in FIG. 2A, to the inner side by the width of the trench T11.

The four third L patterns 71, 72, 73, and 74 are formed by wiring lines P12, P13, P16, and P17 including lines L2, L3, L6, L7, each of which has a width less than the resolution limit shown in FIG. 10A, and pads P2, P3, P6, and P7 connected to the lines, respectively. In addition, in the step where the second original pattern 2P is formed, patterns corresponding to the wiring lines P11, P14, P15, and P18 shown in FIG. 10A are not formed.

### Second Lithography Process:

Then, the second lithography process is performed. In the second lithography process, first, as shown in FIGS. 8A and 8B, a second photoresist pattern 7 is formed on the semiconductor substrate formed with the second original pattern 2P. The second photoresist pattern 7 covers the entire first wiring pattern forming region (rectangular region specified by the first photoresist pattern 1 indicated by reference numeral M11 in FIGS. 1A and 1C) and includes a unified pattern, which has an opening in a predetermined portion, and a normal pattern which has a dimensional equal to or more than the resolution limit and is formed in the second wiring pattern forming region, which becomes the peripheral circuit region 2000, simultaneously with the unified pattern.

The unified pattern is for forming the first wiring pattern 10A shown in FIG. 10A, and the normal pattern is for forming the second wiring pattern 10B. In the present embodiment, the second photoresist pattern 7 having the unified pattern and the normal pattern is formed in the second lithography process. Accordingly, the desired wiring pattern 10 including the first and second wiring patterns 10A and 10B is simultaneously formed eventually.

In the unified pattern, three openings W1, W2, and W3 are regularly provided, as shown in FIG. 8A. These openings W1, W2, and W3 are provided in order to form patterns corresponding to the shapes of the wiring lines P11 to P18 by dividing the second mask layer 2 so that patterns corresponding to the wiring lines P11, P14, P15, and P18 shown in FIG. 10A, which are not formed in the step where the second original pattern 2P shown in FIGS. 7A and 7B is formed, appear.

As shown in FIG. 8A, in each of the openings W1, W2, and W3, a region 1f interposed between the end 1d of the line of each of the first L patterns 21, 22, 23, and 24 (refer to FIG. 1C), which form the first photoresist pattern 1, and the edge 1e of the pad of the adjacent first L pattern is disposed. For example, with regard to the opening W1, the region 1f interposed between the end 1d of the line L33 of the first L pattern 22 in FIG. 1C and the edge 1e of the pad P66 of the adjacent first L pattern 23 is disposed.

Changing the point of view using FIG. 7A, for example, the opening W1 serves to expose a region surrounded by, in the third L patterns 72 and 73 of the arbitrary adjacent third L patterns 71, 72, 73, and 74 of the second original pattern 2P: a horizontal line including the end of the line L33a located at the opposite side of the pad P33a of the one third L pattern 72; a horizontal line including the end of the pad P63 of the other third L pattern 73 which is opposite the horizontal line including the end of the line L33a; a vertical line including the end of the line L33a in the vertical direction at the side where the width of the line L33a of the one third L pattern 72 increases; and a vertical line including the edge of the second mask layer 2 which is opposite the line L63 in the vertical direction at the side where the line L63 of the other third L pattern 73 extends widthwise with the trench T11 interposed therebetween.

The formation region of the unified pattern of the second photoresist pattern 7 shown in FIG. 8A is a region indicated by reference numeral M12 in FIG. 7A, and specifies the first pattern forming region (memory cell region 1000) including the eight wiring lines P11 to P18 shown in FIG. 10A. As shown in FIG. 8A, the unified pattern is surrounded by an outline 7c, which extends along a direction (X direction) perpendicular to the extension direction of each line, and an outline 7d, which extends along the extension direction (Y direction) of each line.

The upper edge of the outline 7c along the X direction is aligned with the positions of the ends of the pads P2, P4, P6, and P8 shown in FIGS. 10A and 10B, and the lower edge of the outline 7c along the X direction is aligned with the positions of the ends of the pads P1, P3, P5, and P7 shown in FIGS. 10A and 10B. In addition, the upper and lower edges of the outline 7c are disposed further at the inner side, by the width of the trench T11 formed by removing the sidewall 51, than the edges 1c of the pads P22, P66, P33, and P77 of the first L patterns 21 to 24 included in the first photoresist pattern 1. That is, the edges of the outline 7c shown in FIG. 8A are aligned with the positions of the Y-direction ends of the pads P23, P63, P33a, and P73 of the third L patterns 71, 72, 73, and 74, and a part of the outline 7c follows the outline of the third mask layer 61.

In addition, the edges of the outline 7d along the Y direction shown in FIGS. 8A and 8B specify the shapes of the wiring lines P11 and P17 located at the outermost side of the first wiring pattern 10A shown in FIGS. 10A and 10B. In the present embodiment, the left edge of the outline 7d along the Y direction shown in FIG. 8A is aligned with the position of the left end of the pad P23 of the third L pattern 71 located at the leftmost end of the second original pattern 2P shown in FIG. 7A. In addition, the right edge of the outline 7d along the Y direction shown in FIG. 8A is aligned with the position of the right end of the first L pattern 24 located at the rightmost end of the first photoresist pattern 1 shown in FIG. 1C.

In the unified pattern of the second photoresist pattern 7 shown in FIG. 8A, three sides including a left side, an upper side, and a lower side are located inside by the width of the trench T11 with respect to the first wiring pattern forming region M11 shown in FIGS. 1A to 1C, and only the right side covers a rectangular region which is the same position as the right side of the first wiring pattern forming region M11. That is, the formation region M12 of the unified pattern of the second photoresist pattern 7 is a region which covers a rectangle with two apexes including the apex (X3, Y3) of the pad P23 of the third L pattern 71 located at the leftmost end in FIG. 7A and the apex (X4, Y4) obtained by shifting the apex of the pad P73 of the third L pattern 74, which is located at the rightmost end, by the width of the trench T11 in the X direction.

In addition, the normal pattern of the second photoresist pattern 7 formed in the second wiring pattern forming region shown in FIG. 8A may have any shape as long as it can be formed simultaneously with the unified pattern in the second lithography process, and there is no particular limitation regarding the shape of the normal pattern.

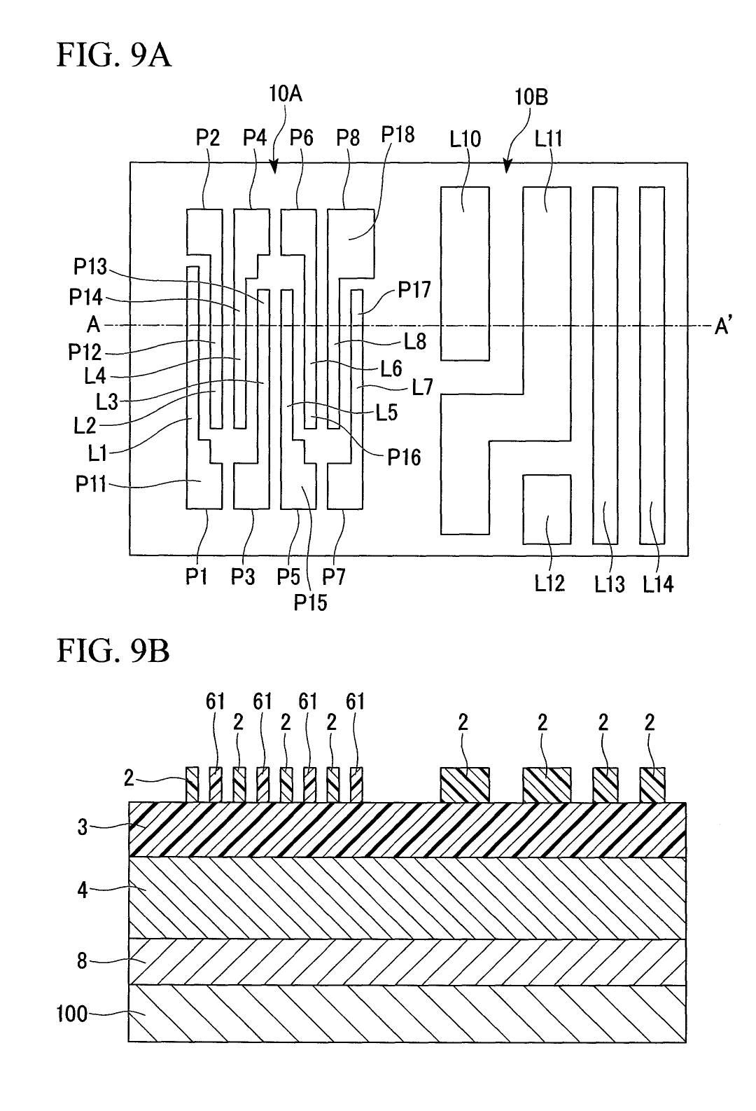

Then, as shown in FIGS. 9A and 9B, the second mask layer 2 whose surface is exposed is removed by the dry etching method or the like using the second photoresist pattern 7 as a mask (second etching process). Then, the second photoresist pattern 7 is removed by the wet etching method or the like. As a result, the first wiring pattern 10A, which includes the lines L1 to L8 with dimensions less than the resolution limit and the pads P1 to P8 disposed at one ends of the lines and also includes the plurality of wiring lines P11 to P18 that are independent L patterns formed by the second mask layer 2 or the third mask layer 61, is formed in the first wiring pattern forming region. At the same time, the second wiring pattern 10B including the wiring lines L10 to L14 with dimensions equal to or more than the resolution limit, which is formed by the second mask layer 2, is formed in the second wiring pattern forming region.

In this step, a pattern equivalent to the wiring pattern 10 shown in FIGS. 10A and 10B is formed. As described previously, the wiring lines L10 to L14 included in the second wiring pattern 10B are shown only in the right region of each drawing for the sake of convenience. However, the wiring lines L10 to L14 may be formed in a region other than the first wiring pattern forming region M11 where the first wiring pattern 10A is formed, without being limited to that described above.

In the present embodiment, parts of the outlines 7c and 7d of the unified pattern, which is formed in the first wiring pattern forming region M11, of the second photoresist pattern 7 shown in FIGS. 8A and 8B are formed along the outline of the third mask layer 61, and the third mask layer 61 is not disposed further at the outer side, in plan view, than the region where the second photoresist pattern 7 is formed. Therefore, the third mask layer 61 is not removed by patterning using the second photoresist pattern 7 as a mask.

In addition, in a step before performing the patterning using the second photoresist pattern 7 as a mask, that is, in a step where the second original pattern 2P is formed, the second mask layer 2 patterned using the first photoresist pattern 1 as a mask is not divided but continues in the frame shape at the outer side of the second mask groove 2a as shown in FIG. 7A.

In the present embodiment, as shown in FIG. 8A, the second photoresist pattern 7 (unified pattern) formed in the first wiring pattern forming region M11 is one unified pattern, the upper edge of the outline 7c along the X direction is aligned with the positions of the ends of the pads P23 and P63 of the third L patterns 71 and 73 shown in FIG. 7A, and the lower edge of the outline 7c along the X direction is aligned with the positions of the ends of the pads P33a and P73 of the third L patterns 72 and 74. Accordingly, by patterning using the second photoresist pattern 7 as a mask, it is possible to align the positions of the ends of the pads P1, P3, P5, P7, which are located at the lower side, and the positions of the ends of the pads P2, P4, P6, P8, which are located at the upper side, of the eight wiring lines P11 to P18 included in the first wiring pattern 10A.

Moreover, in the present embodiment, the openings W1, W2, and W3 are provided at predetermined positions of the unified second photoresist pattern 7 (unified pattern) formed in the first wiring pattern forming region M11, as shown in FIG. 8A. In each opening, the region 1f interposed between the end 1d of each of the lines L22, L33, and L66 of the first L patterns shown in FIG. 1C and the inner edge 1e of each of the pads P33, P66, and P77 facing the end 1d is exposed. Accordingly, the second mask layer 2 connected with the line in a corresponding region between the first L patterns 21 to 24 is separated by the region 1f by etching the second mask layer 2 using the second photoresist pattern 7 as a mask. Specifically, the pad P4 and the line L5 shown in FIG. 9A are separated from each other by etching the second mask layer 2 exposed to the opening W1, for example. Similarly, the pad P1 and the line L4 are separated from each other in the opening W2, and the pad P7 and line L6 are separated from each other in the opening W3. As a result, the wiring lines P11 to P18 which are independent L patterns are formed.

Then, in the present embodiment, as shown in FIGS. 10A and 10B, the first and second wiring patterns 10A and 10B shown in FIGS. 9A and 9B are transferred to the wiring layer 4 disposed below the second mask layer 2 or the third mask layer 61. That is, by etching the first mask layer 3 by the dry etching method or the like using the first and second wiring patterns 10A and 10B as a mask, the first and second wiring patterns 10A and 10B formed by the remaining first mask layer 3 are formed. Then, the first and second wiring patterns 10A and 10B are transferred to the wiring layer 4 by etching the wiring layer 4 by the dry etching method or the like using as a mask the first and second wiring patterns 10A and 10B formed by the first mask layer 3.

As a result, as shown in FIGS. 10A and 10B, the first wiring pattern 10A including the wiring lines P11 to P18 is formed in the first wiring pattern forming region M11 (memory cell region 1000) and at the same time, the second wiring pattern 10B including the wiring lines L10 to L14 is formed in the second wiring pattern forming region (peripheral circuit region 2000).

The wiring pattern forming method of the present embodiment is a method of forming the wiring pattern 10 having the first wiring pattern forming region M11, in which the first wiring pattern 10A including the plurality of wiring lines P11 to P18 with dimensions less than the resolution limit is provided, and the second wiring pattern forming region, in which the second wiring pattern 10B including the plurality of wiring lines L10 to L14 with dimensions equal to or more than the resolution limit is provided. In the wiring pattern forming method of the present embodiment, the first wiring pattern 10A is formed by performing the first lithography process and then performing the second lithography process, and the second wiring pattern 10B is formed simultaneously with the first wiring pattern 10A by performing the second lithography process.

Moreover, in the wiring pattern forming method of the present embodiment, the first wiring pattern 10A can be formed by performing the first lithography process and then performing the second lithography process. In the first lithography process, formation and removal of the sidewall 51 are performed for the second mask layer 2 in which the first original pattern is formed. Accordingly, the second lithography process is the same as a normal lithography process in which a process, such as formation of a sidewall, does not need to be performed. Thus, the first and second wiring patterns 10A and 10B can be simultaneously formed by performing the second lithography process.

Moreover, in the wiring pattern forming method of the present embodiment, the first original pattern 1P having the four second L patterns is formed in the first wiring pattern forming region M11 in the first lithography process. Accordingly, the wiring lines P11 to P18 which are eight L patterns are formed by performing the second lithography process. That is, according to the wiring pattern forming method of the present embodiment, the wiring lines P11 to P18 which include not only lines but also pads and the number of which is twice the number of wiring lines of the first original pattern 1P can be formed by performing the first lithography process and the second lithography process. In addition, in the present embodiment, since the SADP method is performed including pads. Accordingly, since a process of forming pads after forming wiring lines, which has been performed in the known technique, is not required, the entire process can be simplified. As a result, it is possible to avoid a problem in that adjacent patterns are connected to each other due to insufficient alignment of wiring lines and pads.

In the wiring pattern forming method of the present embodiment, the first original pattern 1P is used which has a plurality of second L patterns, each of which has a line and a pad obtained by increasing the width of one end of the line in only one direction, and in which the plurality of second L patterns are aligned in a direction perpendicular to the longitudinal direction of each line, the pad is disposed further at the outer side in the longitudinal direction of the line than the other end of the line of the adjacent second L pattern, and the pads of the adjacent second L patterns are disposed at different ends of the lines in the longitudinal direction. Moreover, the second photoresist pattern 7 is used which has a normal pattern and a unified pattern having the openings W1, W2, and W3 provided thereinside and in which a region, which is interposed between the other end of the line of the second L pattern and the inside edge of the pad of the adjacent second L pattern extending in a direction perpendicular to the longitudinal direction of the line, is disposed in each of the openings W1, W2, and W3. Accordingly, even if the wiring lines P11 to P18 have lines, which are fine patterns with smaller dimensions that are smaller than the resolution limit, and pads obtained by increasing the widths of one ends of the lines, the lines and the pads can be formed simultaneously with high precision using the SADP method. As a result, protruding wiring patterns including pads and lines can be precisely formed with a smaller number of manufacturing processes than that in the case of forming lines and pads separately.

The semiconductor device of the present embodiment includes the wiring unit 11 with the four adjacent wiring lines P14, P13, P15, and P16 each of which includes a line with a width less than the resolution limit and a pad disposed at the end of the line. In the wiring unit 11, a pad is disposed further at the outer side in the longitudinal direction of a line than the other end of a line of one of the adjacent wiring lines. Moreover, among the four wiring lines P14, P13, P15, and P16, the pads P4 and P6 of the wiring lines P14 and P16 located at the outer side and the pads P3 and P5 of the wiring lines P13 and P15 located at the inner side are disposed at different ends of the lines in the longitudinal direction thereof. The pads P4 and P6 of the outer wiring lines are obtained by increasing the widths of the lines inward, and the pads P3 and P5 of the inner wiring lines are obtained by increasing the widths of the lines outward. Accordingly, even if lines are formed by fine patterns with smaller dimensions that are smaller than the resolution limit, the lines and pads can be formed simultaneously with high precision using the SADP method. As a result, the semiconductor device of the present embodiment can have the wiring pattern 10 which can be precisely formed with a smaller number of manufacturing processes than that in the case of forming lines and pads separately.

Moreover, in the wiring pattern forming method of the present embodiment, in the first photoresist pattern 1 formed in the memory cell region 1000 by the first lithography process, the widening directions of the pads P22, P33, P66, and P77 of all of the first L patterns 21 to 24 with respect to the lines L22, L33, L66, and L77 are the same. In addition, the distance D1 in each line is the width D1 of each line of the first wiring pattern 10A, and the distance D2 between a pad (for example, the pad P22) of each of the first L patterns 21 to 24 and a pad (for example, the pad P66), which is adjacent to the pad (for example, the pad P22) with one first L pattern interposed therebetween, is set to the width D2 of the pad of the first wiring pattern 10A. Accordingly, the widths of the pads P1 to P8 of the first wiring pattern 10A are sufficiently ensured. In addition, it is possible to obtain the first wiring pattern 10A with fine patterns, in which the pitch C1 of lines and spaces in the lines L1 to L8 of the first wiring pattern 10A is a half of the pitch C2 of lines and spaces in the lines L22, L33, L66, and L77 of the first L patterns, arrayed at equal distances therebetween.

In addition, in the wiring pattern forming method of the present embodiment, the second and third mask layers 2 and 61 are formed of the same material. Accordingly, when etching the first mask layer 3 using as a mask the first wiring pattern 10A formed by the second and third mask layers 2 and 61, the function of the first wiring pattern 10A as a mask is the same over the entire surface. As a result, since a process of etching the wiring layer 4, which is performed after etching the first mask layer 3, can be precisely performed, the first wiring pattern 10A formed by the wiring layer 4 can be formed with high precision.

In addition, the wiring pattern forming method of the present embodiment includes: a process of forming the first mask layer 3, such as a silicon nitride film, and the second mask layer 2, such as a silicon film, sequentially on the wiring layer 4, such as a tungsten film; a process of patterning the second mask layer 2 using the first photoresist pattern 1 as a mask in the first lithography process; a process of forming the openings W1, W2, and W3 at the predetermined positions of one unified pattern of the second photoresist pattern 7 formed in the memory cell region 1000 such that the region 1f interposed between the end 1d of each of the lines L22, L33, and L66 of the first L patterns 21 to 24 and the inner edge 1e of each of the pads P33, P66, and P77 of the adjacent first L patterns extending in the X direction is disposed in each opening; and a process of forming the lines L1 to L8 and the pads P1 to P8, which are connected to the corresponding lines, simultaneously in the memory cell region 1000 by etching the first mask layer 3 and the wiring layer 4 using the second photoresist pattern 7 as a mask. The process of patterning the second mask layer 2 includes: a process of forming the second mask groove 2a, which corresponds to the shape of the first photoresist pattern 1, in the second mask layer 2 using the first photoresist pattern 1 which has the first L patterns 21 to 24 including the lines L22, L33, L66, and L77 and the pads P22, P33, P66, and P77 obtained by increasing the width of one end 1c of each line in only one direction and in which four first L patterns 21 to 24 are aligned in the X direction, each pad is located further at the outer side in the Y direction than the other ends 1d of lines of the adjacent first L patterns, and pads of the adjacent first L patterns are disposed at different ends of corresponding lines in the Y direction; a process of forming the sidewall 51 on the side wall of the second mask groove 2a, embedding the third mask layer 61, which is formed of the same material as the second mask layer 2, in a region surrounded by the sidewall 51, and removing the sidewall 51; and a process of forming wiring lines, which include lines with widths less than the resolution limit formed by the second mask layer 2 and the third mask layer 61 and pads disposed at the ends of the lines, in the memory cell region 1000 and forming normal wiring lines equal to or more than the resolution limit in the peripheral circuit region 2000 simultaneously with the wiring lines by etching the second mask layer 2 using the second photoresist pattern 7, which is formed in the memory cell region 1000 and the peripheral circuit region 2000, as a mask in the second lithography process. Accordingly, even if the first wiring pattern 10A of the wiring pattern 10 has lines, which are fine patterns with smaller dimensions that are smaller than the resolution limit, and pads obtained by increasing the widths of one ends of the lines, the lines and the pads can be formed simultaneously with high precision using the SADP method. As a result, the first wiring pattern 10A including the protruding wiring lines with the lines L1 to L8 and the pads P1 to P8 can be precisely formed with a smaller number of manufacturing processes than that in the case of forming lines and pads separately.

In addition, although the memory semiconductor device in which the first wiring pattern forming region is the memory cell region 1000 and the second wiring pattern forming region is the peripheral circuit region 2000 has been described an example in the present embodiment, the wiring pattern (semiconductor device) forming method and the semiconductor device of the embodiment are not limited thereto.

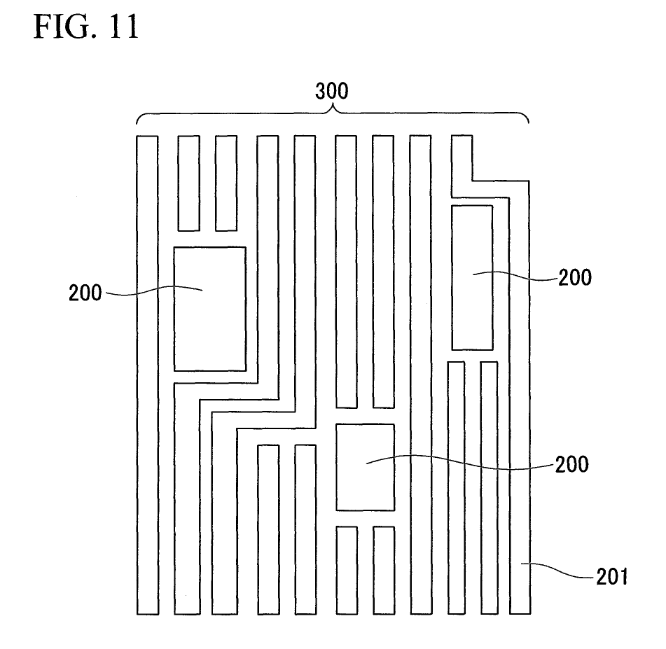

In addition, FIG. 11 is a view illustrating another example of the semiconductor device of the invention. FIG. 11 is a plan view showing an example of a semiconductor device having a complex pattern 300 in which a plurality of first wiring pattern forming regions 200, which are memory cell regions, are present in a second wiring pattern forming region 201 which is a peripheral circuit region. In FIG. 11, first wiring patterns including a plurality of wiring lines with dimensions less than the resolution limit included in the first wiring pattern forming region 200 are omitted for convenience of illustration. As shown in FIG. 11, when the plurality of first wiring pattern forming regions 200 are provided in the semiconductor device, the first wiring patterns provided in the plurality of first wiring pattern forming regions 200 may be different or the same.

In addition, when the plurality of first wiring pattern forming regions are present in the second wiring pattern forming region, the first wiring pattern forming regions may be disposed repeatedly and regularly or may be disposed irregularly. That is, the first wiring pattern forming regions may be arbitrarily disposed in required regions.

In addition, the semiconductor device of the invention may have a complex pattern in which a first wiring pattern forming region where first wiring patterns are formed and a second wiring pattern forming region where second wiring patterns are formed are repeatedly disposed. In this case, the first wiring pattern forming regions which are repeatedly disposed may be the same first wiring pattern or may be different first wiring patterns, and the second wiring pattern forming regions which are repeatedly disposed may be the same second wiring pattern or may be different second wiring patterns.

### Example 1

The wiring pattern 10 shown in FIGS. 10A and 10B was formed using a wiring pattern forming method illustrated below.

First, as shown in FIGS. 1A to 1C, the semiconductor substrate 100 on which the insulating layer 8 serving as an interlayer insulating layer, such as a silicon oxide film, was formed was prepared. In addition, an active region where an element isolation region, a transistor, and the like are formed is formed on the surface of the prepared semiconductor substrate 100. In addition, a contact plug connected to a wiring line, which is eventually formed, is appropriately formed in the silicon oxide film serving as the interlayer insulating layer of the semiconductor substrate 100.

Then, a tungsten film with a thickness of 100 nm serving as the wiring layer 4 was formed on the semiconductor substrate 100, and a silicon nitride film with a thickness of 100 nm serving as the first mask layer 3 and a silicon film with a thickness of 100 nm serving as the second mask layer 2 were sequentially formed on the tungsten film using the CVD method.

The silicon film serving as the second mask layer 2 was formed using an LP-CVD method in which monosilane was used as source gas and the film forming temperature was set to 530° C.

Then, the first lithography process was performed. First, a photoresist layer was formed on the second mask layer 2, and the first photoresist pattern 1 having the first L patterns 21, 22, 23, and 24 shown in FIG. 1C was formed in the first wiring pattern forming region M11 serving as the memory cell region 1000 using a lithography process.

In addition, the pitch C2 of line and space of the lines L22, L33, L66, and L77 of the first photoresist pattern 1 was set to 100 nm, and the space D1 between the lines was set to 25 nm. Accordingly, the width of each of the lines L22, L33, L66, and L77 was 75 nm. In the present embodiment, the minimum processing dimension specified by lithography was set to 50 nm.

Subsequently, as shown in FIGS. 2A and 2B, the first original pattern 1P having four second L patterns formed by the second mask grooves 2a was formed in the second mask layer 2 by performing dry etching of the second mask layer 2 using the first photoresist pattern 1 as a mask. Then, the first photoresist pattern 1 was removed using the wet etching method.

Then, as shown in FIGS. 3A and 3B, the sidewall layer 5, such as a silicon oxide film with a thickness of 25 nm, was formed on the entire surface using the LP-CVD method. Monosilane (SiH₄) was used as source gas of the sidewall layer 5 and nitrous oxide (N₂O) was used as oxidation gas under the conditions of the temperature range of 700° C. to 800° C. and the pressure range of 0.1 to 2.0 (Torr).

Then, as shown in FIGS. 4A and 4B, the sidewall 51 with a thickness of 25 nm was formed on the side wall of the second mask groove 2a by etching back the sidewall layer 5 by an anisotropic dry etching method using plasma containing fluorine.

Then, as shown in FIGS. 5A and 5B, the third mask layer 6, such as a silicon film with a thickness of 200 nm, was formed such that the entire second mask groove 2a was embedded using the CVD method.

Then, as shown in FIGS. 6A and 6B, the third mask layer 6 and the second mask layer 2 were etched back using the dry etching method. As a result, the third mask layer 61 embedded in the region surrounded by the sidewall 51 was formed and an upper part of the sidewall 51 was exposed.

Then, as shown in FIGS. 7A and 7B, the sidewall 51 was selectively removed by the wet etching method using a solution containing fluoric acid, so that the surface of the silicon nitride film 3 was exposed. As a result, the trench T11 interposed between the third mask layer 61 and the second mask layer 2 was formed, and the second original pattern 2P having the trench T11 thereinside along the outer periphery of the first original pattern 1P was formed.

Then, the second lithography process was performed. First, as shown in FIGS. 8A and 8B, a photoresist layer was formed on the semiconductor substrate 100 formed with the second original pattern 2P, and the second photoresist pattern 7 having a unified pattern and a normal pattern was formed using the lithography process.

Then, as shown in FIGS. 9A and 9B, the second mask layer 2 whose surface was exposed was removed by dry etching using the second photoresist pattern 7 as a mask, and then the second photoresist pattern 7 was removed by the wet etching method. As a result, the first wiring pattern 10A, which included the lines L1 to L8 with a width of 25 nm that was a dimension less than the resolution limit and the pads P1 to P8 connected to the corresponding lines and also included the plurality of wiring lines P11 to P18 that were independent L patterns formed by the second mask layer 2 or the third mask layer 61, was formed in the first wiring pattern forming region. At the same time, the second wiring pattern 10B including the wiring lines L10 to L14 with dimensions equal to or more than the resolution limit, which was formed by the second mask layer 2, was formed in the second wiring pattern forming region.

Then, as shown in FIGS. 10A and 10B, the first mask layer 3 disposed below the second mask layer 2 or the third mask layer 61 was dry-etched using as a mask the first and second wiring patterns 10A and 10B shown in FIGS. 9A and 9B. As a result, the first and second wiring patterns 10A and 10B formed by the remaining first mask layer 3 were formed. Then, the first and second wiring patterns 10A and 10B were transferred to the wiring layer 4 by performing dry etching of the wiring layer 4 using the first and second wiring patterns 10A and 10B, which were formed by the silicon nitride film 3, as a mask. As a result, the wiring pattern 10 including the first and second wiring patterns 10A and 10B was formed.

The pitch C1 of line and space in the lines L1 to L8 of the first wiring pattern 10A of the wiring pattern 10 obtained as described above was 50 nm, which was a half of the pitch C2 of line and space in the lines L22, L33, L66, and L77 of the first photoresist pattern 1.

Even not shown, a semiconductor device having a multi-layered wiring structure was manufactured through a process of forming an interlayer insulating layer, a process of forming a contact hole for exposing the pad surface in the interlayer insulating layer, a contact plug forming process for embedding the contact hole with a conductor, a process of forming an upper wiring line on the interlayer insulating layer including the contact plug, and the like.

In this example, it was possible to form, in the first wiring pattern forming region serving as the memory cell region 1000, the wiring lines P11 to P18 including the lines L1 to L8, which were formed of tungsten with a width of 25 nm that was a dimension equal to or less than the resolution limit, and the pads P1 to P8 which were made of tungsten and were connected to the corresponding lines. In addition, the wiring lines L10 to L14 which were formed of tungsten and had a dimension equal to or more than the resolution limit were formed in the second pattern forming region, which served as the peripheral circuit region 2000, simultaneously with the wiring lines P11 to P18.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method of forming a pattern, the method comprising:
performing a first lithography process that is applied to a first region of a substrate; and
performing a second lithography process that is applied to the first region and to a second region of the substrate, to form a first pattern in the first region, and to form a second pattern in the second region, the first pattern being defined by a first dimension, the first dimension being smaller than a resolution limit of lithography, the second pattern being defined by a second dimension, the second dimension being equal to or greater than the resolution limit of lithography.

2. The method according to claim 1, wherein the first pattern comprises a first wiring pattern comprising a line portion and an expended portion, the line portion has a first width smaller than the resolution limit of lithography, the expended portion is greater in width than the line portion.

3. The method according to claim 1, wherein the first lithography process comprises:
forming a first resist pattern over a first layer, the first layer extending over the first region and the second region of the substrate;
performing a first etching process using the first resist pattern as a first mask to selectively etch the first layer in the first region to form a first-original pattern in the first region;
removing the first resist pattern; and
processing the first-original pattern to form a second-original pattern, the second-original pattern being defined by the first dimension that is smaller than the resolution limit of lithography, and
wherein the second lithography process comprises:
forming a second resist pattern over the first layer; and
performing a second etching process using the second resist pattern as a second mask to selectively etch the first layer in the first region and the second region.

4. The method according to claim 3, wherein the second etching process selectively etches the first layer to form the first pattern in the first region and the second pattern in the second region simultaneously.

5. The method according to claim 3, wherein the first-original pattern comprises a plurality of first L-shaped lines, each of the plurality of first L-shaped lines comprises a line portion and an expanded portion, the first L-shaped lines are aligned at a constant pitch in a first direction, the first direction being perpendicular to a second direction along which the line portions extend, and the expanded portions expand in the first direction, the expanded portion of each of the first L-shaped lines is positioned outside, in the second direction, the line portion of an adjacent one of the first L-shaped lines, and the expanded portions of two adjacent ones of the first L-shaped lines are positioned at opposite sides in the second direction.

6. The method according to claim 5, further comprising:
forming a second layer over the substrate;
forming the first layer over the second layer, before performing the first lithography process,
wherein the first-original pattern is formed in the first layer.

7. The method according to claim 3, wherein performing the second etching process using the second resist pattern as the second mask comprises selectively etching the first layer to form the second pattern in the first layer.

8. The method according to claim 3, wherein processing the first-original pattern to form the second-original pattern comprises:
forming a side wall layer, without filling up first grooves of the first-original pattern, the side wall layer extending on side wall surfaces of the first-original pattern and on an upper surface of the first layer, the side wall layer being different in material than the first layer;
etching back the side wall layer to form side walls on the side wall surfaces of the first-original pattern, the side walls defining second grooves that are narrower than the first grooves;
forming a third layer that fills up the second grooves of the first-original pattern, the third layer being the same in material as the first layer;
etching back the third layer and the first layer so that upper portions of the side walls project from an etched surface of the first layer; and
removing the side walls to form the second-original pattern.

9. The method according to claim 8, wherein the first pattern is formed by performing the second lithography process to the first region having the second-original pattern.

10. The method according to claim 9, wherein the second-original pattern comprises a plurality of second L-shaped lines, each of the plurality of second L-shaped lines comprises a line portion and an expanded portion, the line portion having a first width as the first dimension, the first width is smaller than the resolution limit of lithography, the plurality of second L-shaped lines are aligned in a first direction perpendicular to a second direction along which the plurality of second L-shaped lines are aligned in parallel to each other,
the second resist pattern has an opening that includes first, second, third and fourth edges of the second L-shaped lines, the first and second edges are parallel to each other and extend along the first direction, the third and fourth lines are parallel to each other and extend along the second direction, the first edge is a first edge of the line portion of a first one of the second L-shaped lines, the second edge is a first edge of the expanded portion of a second one of the second L-shaped lines, the second one is adjacent to the first one, the third edge is a second edge of the line portion of the first one of the second L-shaped lines, the fourth edge is a second edge of the expanded portion of the second one of the second L-shaped lines.

11. The method according to claim 10, wherein the second resist pattern has first, second, third and fourth peripheral edges, the first, second and third peripheral edges are positioned inside the peripheral edges of the first region by a width of the second grooves, and the fourth peripheral edge is aligned to the peripheral edge of the first region.

12. The method according to claim 1, wherein the first region is a memory cell region, and the second region is a peripheral circuit region.

13. The method according to claim 1, wherein the first pattern comprises at least one of a word line pattern and a bit line pattern.

14. The method according to claim 1, wherein the first lithography process is performed by using a first resist pattern, the first resist pattern comprises a plurality of third L-shaped lines, each of the plurality of third L-shaped lines comprises a line portion and an expanded portion, the line portion has a first width as the first dimension, the first width is smaller than the resolution limit of lithography, the expanded portion has a second width being three times wider than the first width, the third L-shaped lines are aligned at a constant pitch in a first direction, the first direction being perpendicular to a second direction along which the line portions extend, the first constant pitch is two times greater than the first width, and the expanded portions expand in the first direction.

15. A method of forming a wiring pattern, the method comprising:
performing a first lithography process that is applied to a first region of a substrate; and
performing a second lithography process that is applied to the first region and to a second region of the substrate, to form a first pattern in the first region, and to form a second pattern in the second region, the first pattern comprising first and second lines that are separated by a first space, the first and second lines having a first line width, the first space having a first space width, the first line width and the first space width being smaller than a resolution limit of lithography, the second pattern comprises third and fourth lines that are separated by a second space, the third and fourth lines having a second line width, the second space having a second space width, the second line width and the second space width being equal to or greater than the resolution limit of lithography.

16. The method according to claim 15, wherein the first lithography process comprises:
forming a first resist pattern over a first layer over the substrate, the first layer extending over the first region and the second region of the substrate;
performing a first etching process using the first resist pattern as a first mask to selectively etch the first layer in the first region and form a first-original pattern in the first region;
removing the first resist pattern; and
processing the first-original pattern to form a second-original pattern, the second-original pattern being defined by the first dimension that is smaller than the resolution limit of lithography, and
wherein the second lithography process comprises:
forming a second resist pattern over the first layer; and
performing a second etching process using the second resist pattern as a second mask to selectively etch the first layer in the first region and the second region.

17. The method according to claim 15, wherein the first lithography process is performed by using a first resist pattern, the first resist pattern comprises a plurality of third L-shaped lines, each of the plurality of third L-shaped lines comprises a line portion and an expanded portion, the line portion has a first width as the first dimension, the first width is smaller than the resolution limit of lithography, the expanded portion has a second width being three times wider than the first width, the third L-shaped lines are aligned at a constant pitch in a first direction, the first direction being perpendicular to a second direction along which the line portions extend, the first constant pitch is two times greater than the first width, and the expanded portions expand in the first direction.

18. A method of forming a wiring pattern, the method comprising:
forming a first layer over a substrate having first and second regions;
forming a first resist pattern over the first layer;
performing a first etching process using the first resist pattern as a first mask to selectively etch the first layer in the first region and form a first-original pattern in the first region;
removing the first resist pattern; and
processing the first-original pattern to form a second-original pattern, the second-original pattern being defined by a first dimension that is smaller than a resolution limit of lithography;
forming a second resist pattern over the first layer having the second-original pattern; and
performing a second etching process using the second resist pattern as a second mask to selectively etch the first layer in the first region and the second region, to form a first pattern in the first region, and to form a second pattern in the second region, the first pattern being defined by the first dimension, the second pattern being defined by a second dimension that is equal to or greater than the resolution limit of lithography.

19. The method according to claim 18, wherein processing the first-original pattern to form the second-original pattern comprises:
forming a side wall layer, without filling up first grooves of the first-original pattern, the side wall layer extending on side wall surfaces of the first-original pattern and on an upper surface of the first layer, the side wall layer being different in material than the first layer;
etching back the side wall layer to form side walls on the side wall surfaces of the first-original pattern, the side walls defining second grooves that are narrower than the first grooves;
forming a third layer that fills up the second grooves of the first-original pattern, the third layer being the same in material as the first layer;
etching back the third layer and the first layer so that upper portions of the side walls project from an etched surface of the first layer; and
removing the side walls to form the second-original pattern.

20. The method according to claim 18, wherein the first lithography process is performed by using a first resist pattern, the first resist pattern comprises a plurality of third L-shaped lines, each of the plurality of third L-shaped lines comprises a line portion and an expanded portion, the line portion has a first width as the first dimension, the first width is smaller than the resolution limit of lithography, the expanded portion has a second width being three times wider than the first width, the third L-shaped lines are aligned at a constant pitch in a first direction, the first direction being perpendicular to a second direction along which the line portions extend, the first constant pitch is two times greater than the first width, and the expanded portions expand in the first direction.
